(19) United States
(12) Patent Application Publication
(10) Pub. No.: US 2024/0363797 A1
(43) Pub. Date: Oct. 31, 2024

(54) LIGHT-EMITTING ELEMENT, DISPLAY PANEL, AND DISPLAY DEVICE

(71) Applicant: Tianma Advanced Display Technology Institute (Xiamen) Co., Ltd., Xiamen (CN)

(72) Inventors: Cao LIU, Xiamen (CN); Ping AN, Xiamen (CN)

(73) Assignee: Tianma Advanced Display Technology Institute (Xiamen) Co., Ltd., Xiamen (CN)

(21) Appl. No.: 18/771,090

(22) Filed: Jul. 12, 2024

(30) Foreign Application Priority Data
Mar. 5, 2024 (CN) 202410253456.2

(51) Int. Cl. H01L 33/10; H01L 33/38

(52) U.S. Cl. CPC H01L 33/10; H01L 33/38

(57) ABSTRACT

Provided are a light-emitting element, a display panel, and a display device, where the light-emitting element includes a first electrode, a reflective layer and a first connection electrode; at least a part of a region of the reflective layer is located on one side, facing away from a light emission surface, of the first electrode; and the first electrode receives a signal through the first connection electrode; where the first electrode is connected to the first connection electrode, the reflective layer includes a first reflective region, and the first reflective region and the first connection electrode are located on the same side of the first electrode. The technical schemes of the embodiments of the present disclosure can improve the light emission efficiency of the light-emitting element.

### CROSS-REFERENCE TO RELATED APPLICATION

This application claims priority to Chinese Patent Application No. CN 202410253456.2, filed on Mar. 5, 2024, the disclosure of which is incorporated herein by reference in its entirety.

### TECHNICAL FIELD

The present disclosure relates to the field of display techniques and, in particular, to a light-emitting element, a display panel, and a display device.

### BACKGROUND

Common light-emitting elements include light-emitting diodes (LEDs). At present, the direction of application of LEDs mainly includes LED illumination and LED display. In the field of display, in order to adapt to the design requirements of display panels such as high resolution, low power consumption and miniaturization, the size of LEDs has been gradually reduced, and micro/micron light-emitting diodes (micro-LEDs) came into being. In addition to most of the advantages of the LEDs, the micro-LEDs also have the features of high brightness, high resolution, fast response speed, low power consumption, small size, ease to dismantle, high flexibility and no joint, and can meet most of the display applications.

For micro-LEDs, how to improve their light emission efficiency is always a research focus for research and development personnel, and micro-LEDs need to be optimized continuously.

### SUMMARY

The present disclosure provides a light-emitting element, a display panel, and a display device to improve the light emission efficiency of the light-emitting element.

In a first aspect, the present disclosure provides a light-emitting element. The light-emitting element includes a first electrode, a reflective layer and a first connection electrode.

At least a part of the region of the reflective layer is located on one side, facing away from a light emission surface, of the first electrode.

The first electrode receives a signal through the first connection electrode.

The first electrode is connected to the first connection electrode, the reflective layer includes a first reflective region, and the first reflective region and the first connection electrode are located on the same side of the first electrode.

In a second aspect, based on the same invention concept, the present disclosure provides a display panel. The display panel includes the light-emitting element provided by any of embodiments of the present disclosure.

The display panel includes a first light-emitting element and a second light-emitting element.

In a third aspect, based on the same inventive concept, the present disclosure provides a display device. The display device includes the display panel provided by any of embodiments of the present disclosure.

It is to be understood that the content described in this section is neither intended to identify key or critical features of the embodiments of the present disclosure nor intended to limit the scope of the present disclosure. Other features of the present disclosure become easily understood through the description provided hereinafter.

### BRIEF DESCRIPTION OF DRAWINGS

To illustrate technical schemes in embodiments of the present disclosure more clearly, the drawings used in the description of the embodiments are briefly described below. Apparently, the drawings described below only illustrate some embodiments of the present disclosure, and those of ordinary skill in the art may obtain other drawings based on the drawings described below on the premise that no creative work is done.

FIG. 1 is a structure diagram of a light-emitting element according to an embodiment of the present disclosure;

FIG. 2 is a structure diagram of another light-emitting element according to an embodiment of the present disclosure;

FIG. 3 is a schematic diagram of the layer structure of a reflective layer of the light-emitting element shown in FIG. 1;

FIG. 4 is a structure diagram of another light-emitting element according to an embodiment of the present disclosure;

FIG. 5 is a structure diagram of another light-emitting element according to an embodiment of the present disclosure;

FIG. 6 is a structure diagram of another light-emitting element according to an embodiment of the present disclosure;

FIG. 7 is a structure diagram of another light-emitting element according to an embodiment of the present disclosure;

FIG. 8 is a structure diagram of another light-emitting element according to an embodiment of the present disclosure;

FIG. 9 is a structure diagram of another light-emitting element according to an embodiment of the present disclosure;

FIG. 10 is a structure diagram of another light-emitting element according to an embodiment of the present disclosure;

FIG. 11 is a structure diagram of another light-emitting element according to an embodiment of the present disclosure;

FIG. 12 is a structure diagram of another light-emitting element according to an embodiment of the present disclosure;

FIG. 13 is a structure diagram of another light-emitting element according to an embodiment of the present disclosure;

FIG. 14 is a structure diagram of another light-emitting element according to an embodiment of the present disclosure;

FIG. 15 is a structure diagram of another light-emitting element according to an embodiment of the present disclosure;

FIG. 16 is a structure diagram of another light-emitting element according to an embodiment of the present disclosure;

FIG. 17 is a structure diagram of another light-emitting element according to an embodiment of the present disclosure;

FIG. 18 is a structure diagram of a display panel according to an embodiment of the present disclosure;

FIG. 19 is a section view of the display panel taken along YY′ in FIG. 18;

FIG. 20 is an enlarged view of region Q1 in FIG. 19;

FIG. 21 is an enlarged view of region Q2 in FIG. 19;

FIG. 22 is another section view of the display panel taken along YY′ in FIG. 18;

FIG. 23 is another section view of the display panel taken along YY′ in FIG. 18;

FIG. 24 is another section view of the display panel taken along YY′ in FIG. 18;

FIG. 25 is another section view of the display panel taken along YY′ in FIG. 18;

FIG. 26 is another section view of the display panel taken along YY′ in FIG. 18; and

FIG. 27 is a structure diagram of a display device according to an embodiment of the present disclosure.

Reference list

| | |
|---|---|
| 100 | light-emitting element |
| 01 | P electrode |
| 01 | N electrode |
| 03 | light-emitting layer |
| 04 | P connection electrode |
| 05 | N connection electrode |
| 11 | first electrode |
| 111 | first region |
| 112 | second region |
| 1111 | first protrusion |
| T1 | first top portion |
| B1 | first bottom portion |
| 21 | first connection electrode |
| F5 | first top surface |
| F6 | second top surface |
| F7 | first side surface |
| 12 | second electrode |
| 121 | third region |
| 122 | fourth region |
| 1211 | second protrusion |
| T2 | second top portion |
| B2 | second bottom portion |
| 22 | second connection electrode |
| 3 | reflective layer |
| 31 | first reflective region |
| F1 | first surface |
| F2 | second surface |
| 32 | second reflective region |
| F3 | third surface |
| F4 | fourth surface |
| 30 | Bragg reflective layer |
| 301 | first reflective sub-layer |
| 302 | second reflective sub-layer |
| F0 | light emission surface |
| 4 | current spreading layer |
| 41 | first current spreading layer |
| 42 | second current spreading layer |
| E1 | first direction E2 second direction |
| 200 | display panel |
| 201 | array substrate |
| 101 | first light-emitting element |
| 102 | second light-emitting element |
| 13 | third electrode |
| 14 | fourth electrode |
| 51 | first display region |
| 52 | second display region |
| X1 | first preset direction |
| X2 | second preset direction |
| 300 | display device |

### DETAILED DESCRIPTION

To make the technical schemes of the present disclosure better understood by those skilled in the art, the technical schemes in embodiments of the present disclosure are described below clearly and completely in conjunction with drawings in the embodiments of the present disclosure. Apparently, the embodiments described below are part, not all, of the embodiments of the present disclosure. Based on the embodiments of the present disclosure, all other embodiments obtained by those of ordinary skill in the art on the premise that no creative work is done are within the scope of the present disclosure.

It is apparent to those skilled in the art that various modifications and changes in the present application may be made without departing from the spirit or scope of the present application. Accordingly, the present application is intended to cover modifications and variations of the present application that fall within the scope of the appended claims (the claimed technical schemes) and their equivalents. It is to be noted that the implementations provided by the embodiments of the present application, if not in collision, may be combined with each other.

It is to be noted that, unless otherwise defined, the technical and scientific terms used in the present disclosure have the same meanings as commonly understood by those of ordinary skill in the art in the art to which the present disclosure belongs. The terms “first”, “second” and the like in the present disclosure do not denote any sequence, quantity or priority, but are used to distinguish different components. Words such as “include”, “comprise” and the like are intended to specify that the elements or the objects stated before these terms encompass the elements or the objects and equivalents thereof listed after these terms, but do not preclude the other elements or objects. Words such as “connected”, “connecting” and the like are not restricted to physical or mechanical connections, but may include electrical connections, regardless of direct or indirect connections. “On”, “under”, “left”, “right” and the like are only used to indicate a relative position relationship, and when the absolute position of the object which is described is changed, the relative position relationship may be changed accordingly. In addition, the shape or size of any component in the drawings does not reflect the actual scale, and the purpose is only to illustrate the content of the present disclosure.

FIG. 1 is a structure diagram of a light-emitting element according to an embodiment of the present disclosure. As shown in FIG. 1, the light-emitting element 100 provided by the embodiment of the present disclosure includes a first electrode 11, a reflective layer 3 and a first connection electrode 21. At least a part of the region of the reflective layer 3 is located on one side, facing away from a light emission surface F0, of the first electrode 11. The first electrode 11 receives a signal through the first connection electrode 21. The first electrode 11 is connected to the first connection electrode 21, the reflective layer 3 includes a first reflective region 31, and the first reflective region 31 and the first connection electrode 21 are located on the same side of the first electrode 11.

In this embodiment, the light-emitting element 100 may be a micro-LED. As shown in FIG. 1, the light-emitting element 100 mainly includes a P electrode 01, an N electrode 02, a light-emitting layer 03 located between the P electrode 01 and the N electrode 02, a P connection electrode 04, and an N connection electrode 05. The P electrode 01 is electrically connected to the P connection electrode 04 and receives a signal through the P connection electrode 04. The N electrode 02 is electrically connected to the N connection electrode 05 and receives a signal through the N connection electrode 05. When the light-emitting element needs to be driven to emit light, a suitable positive voltage is applied to the P electrode, a zero voltage or a suitable negative voltage is applied to the N electrode, and electrons and holes may be recombined within the light-emitting layer 03 to generate photons to enable the light-emitting element to emit light. For example, the P electrode 01 may include a P-type semiconductor layer (for example, P-gallium nitride (P-GaN)), and the N electrode may include an N-type semiconductor layer (for example, N-gallium nitride (N-GaN)).

In an embodiment, the first electrode 11 refers to one of the P electrode 01 or the N electrode 02, and the first connection electrode 21 refers to one of the P connection electrode 04 or the N connection electrode 05. As shown in FIG. 1, optionally, the first electrode 11 is the P electrode 01, the first connection electrode 21 is correspondingly the P connection electrode 04, and the first electrode 11 is electrically connected to the first connection electrode 21 and receives a signal through the first connection electrode 21. In other embodiments, optionally, the first electrode 11 is the N electrode 02, and the first connection electrode 21 is correspondingly the N connection electrode 05.

As shown in FIG. 1, in this embodiment, the light-emitting element 100 further includes a reflective layer 3. The reflective layer 3 includes a first reflective region 31, and the first reflective region 31 and the first connection electrode 21 are located on the same side of the first electrode 11. The reflective layer 3 has a reflection effect on the light.

With reference to FIG. 1, the first reflective region 31 may be understood as the part of the reflective layer 3 that is disposed corresponding to the first electrode 11 (part of the reflective layer 3 which overlaps the first electrode 11 in the thickness direction of the light-emitting element 100), and the first reflective region 31 and the first connection electrode 21 are located on the same side of the first electrode 11. For example, FIG. 1 is illustrated by using an example in which the first electrode 11 is the P electrode 01 and the first reflective region 31 refers to the part of the reflective layer 3 that is disposed corresponding to the P electrode 01.

With reference to FIG. 1, to avoid the light emission of the light-emitting element being affected, the circuit or the wire structure for transmitting an electric signal for the first electrode 11 is generally located on one side, facing away from the light emission surface F0 of the light-emitting element, of the first electrode 11, and the first connection electrode 21 is thus located on one side, facing away from the light emission surface F0, of the first electrode 11. At the same time, in an embodiment, by setting the light-emitting element 100 to include the reflective layer 3 and by setting the reflective layer 3 to have the first reflective region 31 that is on the same side of the first electrode 11 as the first connection electrode 21, the first connection electrode 21 is thus located on one side, facing away from the light emission surface F0, of the first electrode 11, and the light incident from the light-emitting layer 03 onto the side on which the first connection electrode 21 is located may at least be reflected by the first reflective region 31 of the reflective layer 3 to the light emission surface F0, thereby improving the light emission efficiency of the light-emitting element to a certain extent.

With reference to FIG. 1, when the light emission surface F0 of the light-emitting element 100 mainly corresponds to the region where the P electrode 01 is located, the P electrode 01 may serve as the first electrode 11, and the reflective layer 3 is set to include at least the first reflective region 31 disposed corresponding to the P electrode 01 to reflect most of the light to the light emission surface F0 by the first reflective region 31, thereby improving the light emission efficiency of the light-emitting element.

In summary, in some embodiments of the present disclosure, by disposing a light-emitting element including a reflective layer and making at least a part of the region of the reflective layer be located on one side of the first electrode facing away from a light emission surface and the reflective layer have a first reflective region that is on the same side of the first electrode as the first connection electrode, light may at least be reflected by the first reflective region of the reflective layer to reflect the light incident onto the side on which the first connection electrode is located to the light emission surface, thereby reducing the waste of light energy and improving the light emission efficiency of the light-emitting element.

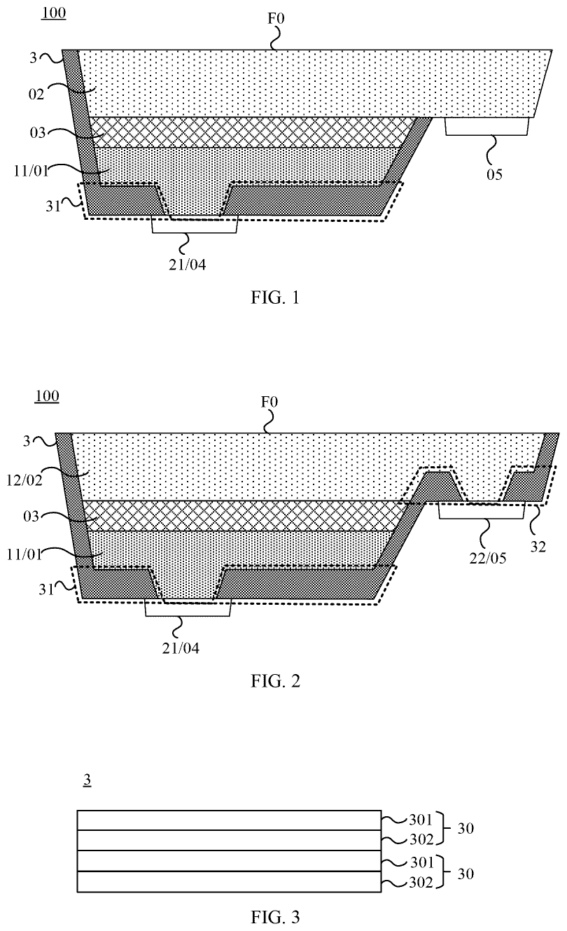

On the basis of the embodiment described above, FIG. 2 is a structure diagram of another light-emitting element according to an embodiment of the present disclosure. As shown in FIG. 2, the light-emitting element 100 further includes a second electrode 12 and a second connection electrode 22. The second electrode 12 is connected to the second connection electrode 22 and receives a signal through the second connection electrode 22. Optionally, at least a part of the region of the reflective layer 3 is located on one side, facing away from the light emission surface F0, of the second electrode 12. The reflective layer 3 includes a second reflective region 32, and the second reflective region 32 and the second connection electrode 22 are located on the same side of the second electrode 12.

In an embodiment, the first electrode 11 refers to one of the P electrode 01 or the N electrode 02, and the second electrode 12 refers to the other one of the P electrode 01 or the N electrode 02; the first connection electrode 21 refers to one of the P connection electrode 04 or the N connection electrode 05, and the second connection electrode 22 refers to the other one of the P connection electrode 04 or the N connection electrode 05. For example, FIG. 2 is illustrated by using an example in which the first electrode 11 is the P electrode 01, the second electrode 12 is the N electrode 02, the first connection electrode 21 is the P connection electrode 04, and the second connection electrode 22 is the N connection electrode 05. The above setting manner is not the only one. In other embodiments, optionally, the first electrode 11 is the N electrode 02, the second electrode 12 is the P electrode 01, the first connection electrode 21 is the N connection electrode 05, and the second connection electrode 22 is the P connection electrode 04.

With the above description, the second reflective region 32 may be understood as the part of the reflective layer 3 that is disposed corresponding to the second electrode 12 (the part of the reflective layer 3 which overlaps the second electrode 12 in the thickness direction of the light-emitting element 100), and the second reflective region 32 and the second electrode 12 are located on one side, facing away from the light emission surface F0, of the second electrode 12. In this embodiment, by setting the reflective layer 3 to include both the first reflective region 31 and the second reflective region 32, the light emission efficiency of the light-emitting element can be further improved.

As shown in FIG. 2, as a feasible implementation, optionally, the reflective layer 3 covers the sidewalls of the P electrode 01, the N electrode 02 and the light-emitting layer 03, covers a part of the surface of one side, facing away from the light emission surface F0, of the P electrode 01, which is not in contact/connected to the P connection electrode 04, and also covers a part of the surface of one side, facing away from the light emission surface F0, of the N electrode 02, which is not in contact/connected to the N connection electrode 05. In this manner, by almost fully covering the light nonemission surface of the light-emitting element with the reflective layer 3, the light emission efficiency of the light-emitting element can be effectively improved under the reflection effect of the reflective layer 3 on the light, without affecting the reception of the electric signal by the P electrode 01 and the N electrode 02.

FIG. 3 is a schematic diagram of the layer structure of a reflective layer of the light-emitting element shown in FIG. 1. As shown in FIG. 3, optionally, the reflective layer 3 includes N Bragg reflective layers 30, where N≥1. At least one N Bragg reflective layer 30 each includes a first reflective sub-layer 301 and a second reflective sub-layer 302. The refractive index of the first reflective sub-layer 301 is different from the refractive index of the second reflective sub-layer 302 and/or the thickness of the first reflective sub-layer 301 is different from the thickness of the second reflective sub-layer 302.

In an embodiment, with reference to FIG. 3, for any Bragg reflective layer 30, the first

reflective sub-layer 301 and the second reflective sub-layer 302 may be set to have different refractive indexes and the same thickness, the first reflective sub-layer 301 and the second reflective sub-layer 302 may be set to have different thicknesses and the same refractive index, or the first reflective sub-layer 301 and the second reflective sub-layer 302 may be set to have different thicknesses and different refractive indexes. In this manner, when the light is incident onto the reflective layer 3, under the setting of the light paths of the light which passes through the layers with different refractive indexes and/or different thicknesses in the Bragg reflective layer 30, the reflection can be enhanced, thereby improving the light emission efficiency of the light-emitting element. In addition, the Bragg reflective layer 30 may be an insulating layer. In this embodiment, by setting the reflective layer 3 to include at least one Bragg reflective layer 30, the signal connection (for example, the signal connection between the first electrode 11 and the first connection electrode 21) between the electrodes in the light-emitting element can be avoided being affected, thereby guaranteeing the product reliability of the light-emitting element.

It is to be noted that FIG. 3 is illustrated by using an example in which the reflective layer 3 includes two Bragg reflective layers 30. In other embodiments, the reflective layer 3 may include only one Bragg reflective layer 30 or may include more Bragg reflective layers 30, which is not limited to the embodiments of the present disclosure.

It is to be further noted that for different Bragg reflective layers 30, the refractive index and the thickness of the first reflective sub-layer 301 and the refractive index and the thickness of the second reflective sub-layer 302 may be set in the same manner or may be set in different manners, which is not limited to the embodiments of the present disclosure.

As shown in FIG. 2, optionally, the first reflective region 31 is located between the layer in which the first electrode 11 is located and the layer in which the first connection electrode 21 is located.

In one aspect, the first reflective region 31 being located between the layer in which the first electrode 11 is located and the layer in which the first connection electrode 21 is located may be understood to mean that the preparation process of the reflective layer 3 is performed between the preparation process of the first electrode 11 and the preparation process of the first connection electrode so that the first reflective region 31 is located between the layer in which the first electrode 11 is located and the layer in which the first connection electrode 21 is located. The sequence of the three is that the first electrode 11 is in front, the reflective layer 3 is in the middle, and the first connection electrode 21 is at the end.

In another aspect, the first reflective region 31 being located between the layer in which the first electrode 11 is located and the layer in which the first connection electrode 21 is located may be understood to mean that in the thickness direction of the light-emitting element 100, the layer thickness region occupied by the first reflective region 31 is located between the layer thickness region occupied by at least a part of the first electrode 11 and the layer thickness region occupied by at least a part of the first connection electrode 21, as long as at least a part of the first electrode 11 is located on one side, facing away from the first connection electrode 21, of the first reflective region 31 and at least a part of the first connection electrode 21 is located on one side, facing away from the first electrode 11, of the first reflective region 31. For example, in a direction parallel to the light emission surface F0 of the light-emitting element, the first reflective region 31 may overlap a part of the first electrode 11 and/or the first reflective region 31 may overlap a part of the first connection electrode 21. In other words, the light-emitting element is cut along the virtual plane parallel to the light emission surface F0 of the light-emitting element, and in the section view, both the first electrode 11 and the first reflective region 31 may exist and/or both the first connection electrode 21 and the first reflective region 31 may exist. The above structure may be understood as that the first reflective region 31 is located between the layer in which the first electrode 11 is located and the layer in which the first connection electrode 21 is located. For example, FIG. 2 is illustrated by using an example in which the first reflective region 31 is in an overlapping relationship with a part of the first electrode 11 in the direction parallel to the light emission surface F0.

The temperature of the light-emitting element will be raised in the performance test stage (for example, during the high temperature test) or in the light emission stage after the light-emitting element is put into use, and the first connection electrode 21 is generally made of a metal material. Therefore, when the temperature of the light-emitting element is raised, the first connection electrode 21 may be expanded to a certain extent, and if the first connection electrode 21 is pressed by neighboring layers in the expansion process, the first connection electrode 21 is prone to peeling, resulting in a poor connection between the first connection electrode 21 and the first electrode.

In this embodiment, when the reflective layer 3 adopts the Bragg reflective layer design, the thermal expansion coefficient of the reflective layer 3 is less than the thermal expansion coefficient of the first connection electrode 21, and thus, the first reflective region 31 may press the first connection electrode 21, restricting the thermal expansion of the first connection electrode 21. The greater the pressure, the higher the risk of the peeling of the first connection electrode 21. In this regard, in this embodiment, by setting the first reflective region 31 to be located between the layer in which the first electrode 11 is located and the layer in which the first connection electrode 21 is located, at least a part of the first connection electrode 21 may be located on one side, facing away from the first electrode 11, of the first reflective region 31 to reduce the degree of pressure on the first connection electrode 21 from the first reflective region 31, thereby solving the problem of the peeling of the first connection electrode 21, ensuring a reliable connection between the first connection electrode 21 and the first electrode 11 and improving the product reliability.

Similarly, as shown in FIG. 2, optionally, the second reflective region 32 is located between the layer in which the second electrode 12 is located and the layer in which the second connection electrode 22 is located.

To reduce the complexity of the preparation process, the first reflective region 31 and the second reflective region 32 may be of a similar design, and the structure design of the light-emitting element will be further described in detail below by using the region where the first reflective region 31 is located as an example.

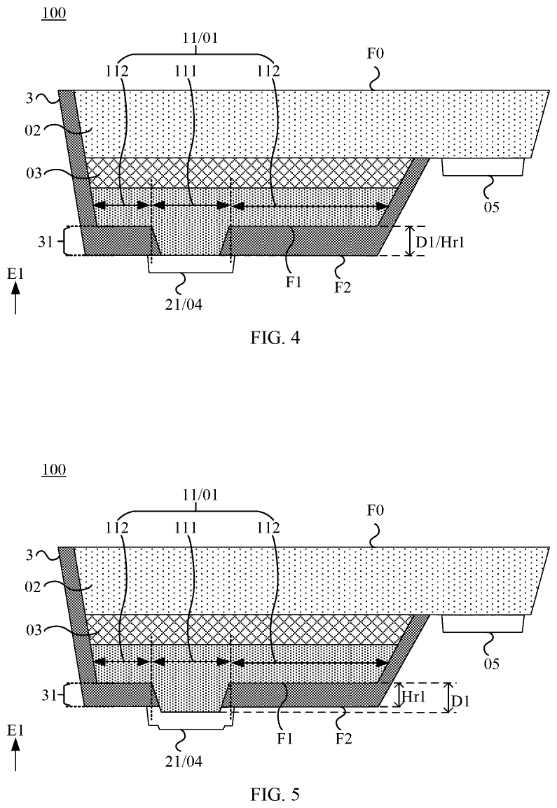

FIG. 4 is a structure diagram of another light-emitting element according to an embodiment of the present disclosure. As shown in FIG. 4, optionally, the first electrode 11 includes a first region 111 and a second region 112. The first region 111 is connected to the first connection electrode 21. The spacing between the second region 112 and the layer in which the first connection electrode 21 is located in a first direction E1 is D1, where the first direction E1 is a direction perpendicular to the surface of the light-emitting element 100, and D1>0.

It is to be noted that FIG. 4 is illustrated by using an example in which the first region 111 is in direct contact with the first connection electrode 21 to achieve the electrical connection between the first electrode 11 and the first connection electrode 21, and the above setting is non-limiting. In other embodiments, the first region 111 of the first electrode 11 may be electrically connected to the first connection electrode 21 indirectly through other layers.

As shown in FIG. 4, in an embodiment, by setting the first electrode 11 to include a first region 111 and a second region 112 and by setting the spacing D1 between the second region 112 of the first electrode 11 and the layer in which the first connection electrode 21 is located in the first direction E1 to meet the condition of D1>0, in one aspect, the electrical connection between the first electrode 11 and the first connection electrode 21 can be achieved through the first region 111 of the first electrode 11, and in another aspect, a gap with a height of D1 (D1>0) can be formed between the layer in which the second region 112 of the first electrode 11 is located and the layer in which the first connection electrode 21 is located. The gap can be used to accommodate the first reflective region 31 of at least the partial thickness to reduce the overlapping area between the first reflective region 31 and the first connection electrode 21 in the direction parallel to the light emission surface F0 and increase the part of the first connection electrode 21 located on one side, facing away from the first electrode 11, of the first reflective region 31. In this manner, the most of the first connection electrode 21 is located on one side, facing away from the first electrode 11, of the first reflective region 31, thereby reducing or even eliminating the pressure on the first connection electrode 21 from the first reflective region 31, reducing the risk of the peeling of the first connection electrode 21 and ensuring the reliable connection between the first connection electrode 21 and the first electrode 11.

FIG. 5 is a structure diagram of another light-emitting element according to an embodiment of the present disclosure. With reference to FIGS. 4 and 5, the thickness of the first reflective region 31 in the first direction E1 is Hr1. As a feasible implementation, optionally, D1≥Hr1. For example, FIG. 4 is illustrated by using an example of D1=Hr1 and FIG. 5 is illustrated by using an example of D1>Hr1.

With reference to FIG. 4, if D1<Hr1, that is, when the lower surface of the first reflective region 31 exceeds the lower surface of the first region 111 of the first electrode 11, only a part of the first reflective region 31 is located in the above gap, the first reflective region 31 still presses the first connection electrode 21 to a certain extent when the first connection electrode 21 is thermally expanded, and the first connection electrode 21 may still be prone to peeling. In view of this, with reference to FIGS. 4 and 5, in this embodiment, by setting the height of the gap to be greater than or equal to the thickness of the first reflective region 31, that is, D1≥Hr1, the gap between the second region 112 of the first electrode 11 and the first connection electrode 21 can be sufficient to accommodate the first reflective region 31 of the full thickness to enable the lower surface of the first reflective region 31 to be flush with the lower surface of the first region 111 of the first electrode 11 (as shown in FIG. 4) or even inwardly retracted (as shown in FIG. 5). In this manner, the first connection electrode 21 connected to the first region 111 can be prevented from being pressed by the first reflective region 31 and thermally expanded freely without the risk of peeling, thereby ensuring the reliable connection between the first electrode 11 and the first connection electrode 21.

With continued reference to FIG. 4, the first reflective region 31 includes a first surface F1 and a second surface F2. Optionally, the first surface F1 is in contact with the second region 112 of the first electrode 11, and the second surface F2 is in contact with the first connection electrode 21. In this case, only the reflective layer 3 is included in the gap between the second region 112 of the first electrode 11 and the first connection electrode 21.

It is to be noted that when D1>Hr1, FIG. 5 is illustrated by using an example in which only the reflective layer 3 is included in the gap between the second region 112 of the first electrode 11 and the first connection electrode 21, that is, by using an example in which the first surface F1 of the first reflective region 31 is in contact with the second region 112 of the first electrode 11 and the second surface F2 of the first reflective region 31 is in contact with the first connection electrode 21, and the above setting is non-limiting. In other embodiments, when D1>Hr1, other layers may also be included in the gap between the second region 112 of the first electrode 11 and the first connection electrode 21.

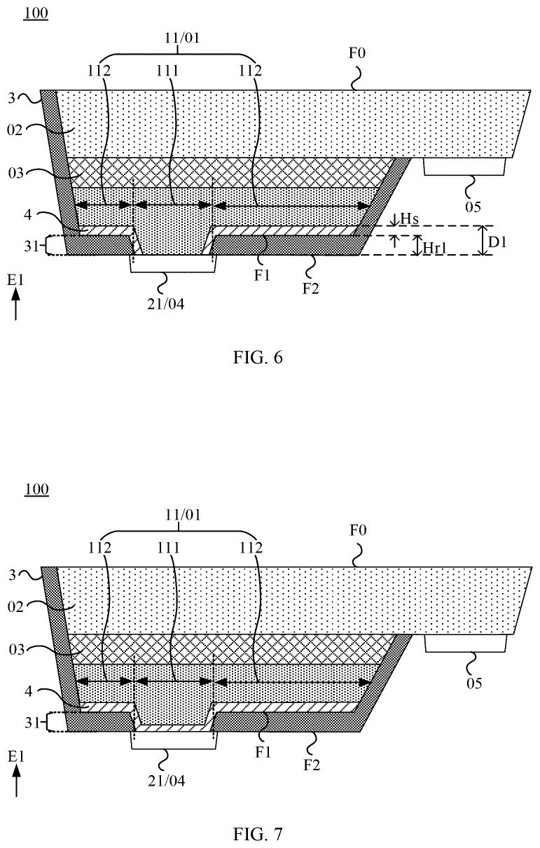

For example, FIG. 6 is a structure diagram of another light-emitting element according to an embodiment of the present disclosure. As shown in FIG. 6, optionally, the light-emitting element 100 further includes a current spreading layer 4, and the first reflective region 31 includes a first surface F1 and a second surface F2. The current spreading layer 4 is located between the first surface F1 and the second region 112 of the first electrode 11, and the second surface F2 is in contact with the first connection electrode 21. The current spreading layer 4 mainly has the function of current drainage. By disposing the current spreading layer 4 between the first surface F1 of the first reflective region 31 and the second region 112 of the first electrode 11, an ohmic contact is formed between the first electrode 11 and the first connection electrode 21 through the current spreading layer 4, thereby improving the conductivity performance.

As shown in FIG. 6, the thickness of the current spreading layer 4 in the first direction E1 is Hs. It is to be noted that FIG. 6 is illustrated by using an example in which the sum of the thickness of the current spreading layer 4 and the thickness of the first reflective region 31 is equal to the height of the gap between the second region 112 of the first electrode 11 and the first connection electrode 21 (that is, Hs+Hr1=D1), and the above setting is non-limiting. In other embodiments, it is feasible that Hs+Hr1<D1.

It is to be further noted that FIG. 6 is illustrated by using an example in which the current spreading layer 4 covers the sidewall of the first region 111 of the first electrode 11, and the above setting is non-limiting. FIG. 7 is a structure diagram of another light-emitting element according to an embodiment of the present disclosure. As shown in FIG. 7, the current spreading layer 4 may cover the sidewall of the first region 111 of the first electrode 11 and the surface on one side, close to the first connection electrode 21, of the first region 111, thereby further improving the conductivity performance.

As shown in FIG. 6, optionally, in the first direction E1, Hs<Hr1, that is, the thickness of the current spreading layer 4 is less than the thickness of the first reflective region 31.

To ensure the reflection effect of the reflective layer 3 on the light, the reflective layer 3 needs to have a certain thickness. For example, when the reflective layer 3 adopts the Bragg reflective layer design, the reflective layer 3 includes at least one Bragg reflective layer which each includes a first reflective sub-layer and a second reflective sub-layer with different refractive indexes and/or different thicknesses, and the thickness of the reflective layer 3 is thick. Since the current spreading layer 4 is mainly used to improve the electrical conductivity between the first electrode 11 and the first connection electrode 21, the requirement of the current spreading layer 4 for the conductivity property is higher than its requirement for the thickness. Therefore, optionally, the thickness Hs of the current spreading layer 4 is set to be less than the thickness Hr1 of the first reflective region 31, thereby ensuring both the conductivity of the current spreading layer 4 and the reflection effect of the reflective layer 3 on the light.

Optionally, at least one side surface of the first reflective region 31 is in contact with the first region 111 of the first electrode 11 (with reference to FIG. 4) or at least one side surface of the first reflective region 31 is in contact with the current spreading layer 4 (with reference to FIG. 6).

In an embodiment, as shown in FIGS. 4 and 6, part of the first region 111 of the first electrode 11 protrudes towards the first connection electrode 21 as compared to the second region 112. In one aspect, the electrical connection between the first electrode 11 and the first connection electrode 21 can be achieved through the first region 111, and in another aspect, a gap for accommodating the reflective layer 3 can be formed between the second region 112 and the first connection electrode 21. In this embodiment, by setting the protrusion portion of the first region 111 to be in direct contact with the side surface of the first reflective region 31 or by setting the protrusion portion of the first region 111 to be in contact with the side surface of the first reflective region 31 through the current spreading layer 4, the reflective layer 3 can be disposed as much as possible on one side, facing away from the light emission surface F0, of the light-emitting element to enable the reflective layer 3 to sufficiently reflect the light and avoid the light leaking out from the side facing away from the light emission surface F0, thereby improving the light emission efficiency of the light-emitting element.

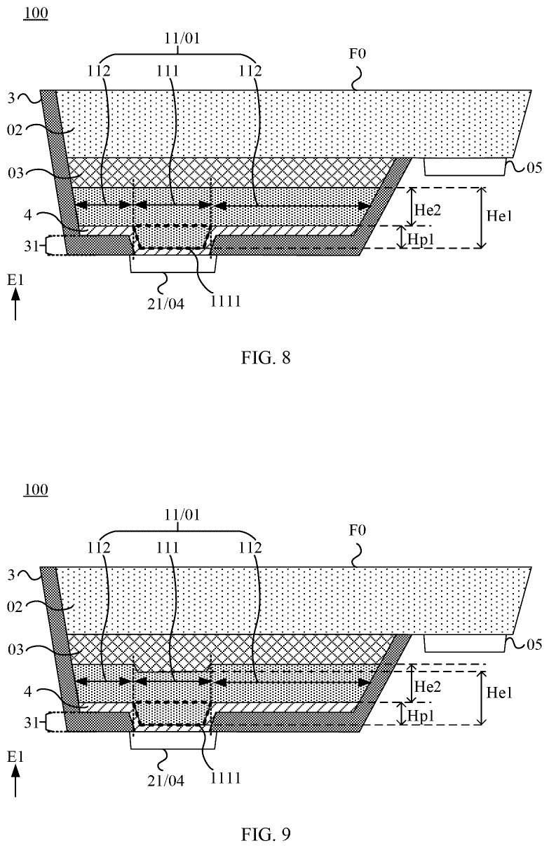

FIG. 8 is a structure diagram of another light-emitting element according to an embodiment of the present disclosure. With reference to FIG. 8, optionally, the thickness of the first region 111 in the first direction E1 is He1, and the thickness of the second region 112 in the first direction E1 is He2, where He1>He2. In an embodiment, to achieve the connection between the first electrode 11 and the first connection electrode 21 and form the accommodating space for the first reflective region 31, the first region 111 of the first electrode 11 protrudes towards the first connection electrode 21 as compared to the second region 112, and thus, the thickness He1 of the first region 111 of the first electrode 11 is greater than the thickness He2 of the second region 112 of the first electrode 11.

As shown in FIG. 8, the first region 111 includes a first protrusion 1111. The first protrusion 1111 is located on one side, facing the first connection electrode 21, of the first region 111. Optionally, the thickness of the first protrusion 1111 in the first direction E1 is Hp1, where He1−Hp1≤He2.

The first protrusion 1111 is a part of the first region 111 that protrudes towards the first connection electrode 21 as compared to the second region 112.

It is to be noted that FIG. 8 is illustrated by using an example of He1−Hp1=He2. In this case, the surface of one side, facing away from the first connection electrode 21, of the first electrode 11 is planar, that is, the upper surface of the first region 111 is flush with the upper surface of the second region 112. The above setting is non-limiting. For example, FIG. 9 is a structure diagram of another light-emitting element according to an embodiment of the present disclosure. As shown in FIG. 9, in other embodiments, due to process limitations or other reasons, the surface of one side, facing away from the first connection electrode 21, of the first electrode 11 is nonplanar. For example, the upper surface of the first region 111 shown in FIG. 9 is downwardly recessed as compared to the upper surface of the second region 112. In this case, the thickness He1 of the first region 111, the thickness He2 of the second region 112 and the thickness Hp1 of the first projection 1111 meet the condition of He1−Hp1 <He2.

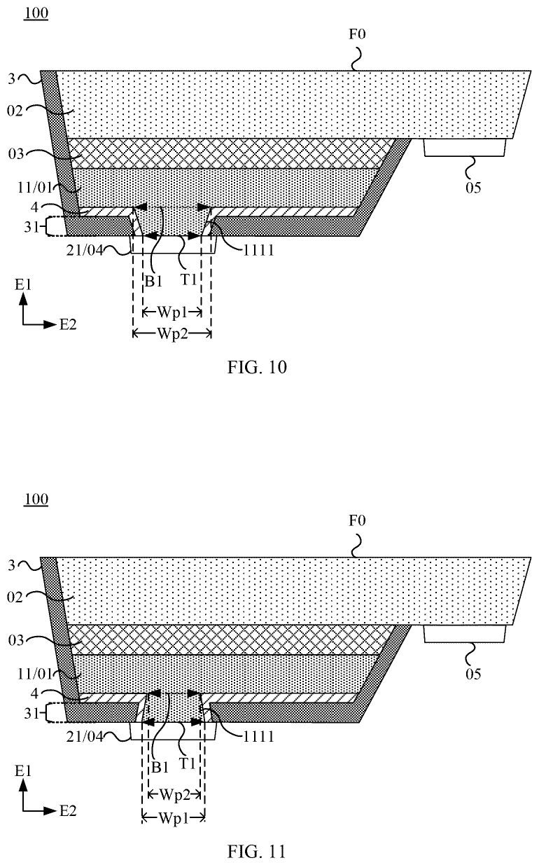

FIG. 10 is a structure diagram of another light-emitting element according to an embodiment of the present disclosure. As shown in FIG. 10, optionally, the first protrusion 1111 includes a first top portion T1 and a first bottom portion B1. The first top portion T1 is connected to the first connection electrode 21, the width of the first top portion T1 in a second direction E2 is Wp1, and the width of the first bottom portion B1 in the second direction E2 is Wp2, where the second direction E2 is perpendicular to the first direction E1, and Wp1≠Wp2.

In an embodiment, the first direction E1 is a direction perpendicular to the surface (for example, the light emission surface F0) of the light-emitting element 100, the second direction E2 is perpendicular to the first direction E1, and thus, the second direction E2 may be any direction parallel to the surface of the light-emitting element 100. With reference to FIG. 10, in this embodiment, by setting the width Wp1 of the first top portion T1 to be not equal to the width Wp2 of the first bottom portion B1, the section shape of the first protrusion 1111 on a cross-section perpendicular to the surface of the light-emitting element 100 is trapezoid-like, thereby meeting different design requirements.

For example, as shown in FIG. 10, as a feasible implementation, optionally, Wp1<Wp2. Through the above setting, the connection region between the first electrode 11 and the first connection electrode 21 becomes relatively narrow to make the region where the reflective layer 3 is disposed as large as possible, thereby sufficiently ensuring the light emission effect and reducing the waste of light energy.

FIG. 11 is a structure diagram of another light-emitting element according to an embodiment of the present disclosure. As shown in FIG. 11, as another feasible implementation, optionally, Wp1>Wp2. Through the above setting, the connection region between the first electrode 11 and the first connection electrode 21 becomes relatively wide, and when the overlapping area/contact area between the first electrode 11 and the first connection electrode 21 is required to be large or when the requirement for connection fastness is high, the above setting can be selected to meet the design requirements, thereby sufficiently ensure the efficient transmission of signals.

With reference to FIG. 9, optionally, the first region 111 and the second region 112 of the first electrode 11 are formed integrally and/or the first region 111 and the second region 112 of the first electrode 11 contain the same material. Through such a setting, in one aspect, an accommodating space for the first reflective region 31 can be formed, and in another aspect, the electrical connection between the first electrode 11 and the first connection electrode 21 can be achieved through the protrusion portion of the first region 111 of the first electrode 11 without the need to additionally set a via in the reflective layer 3.

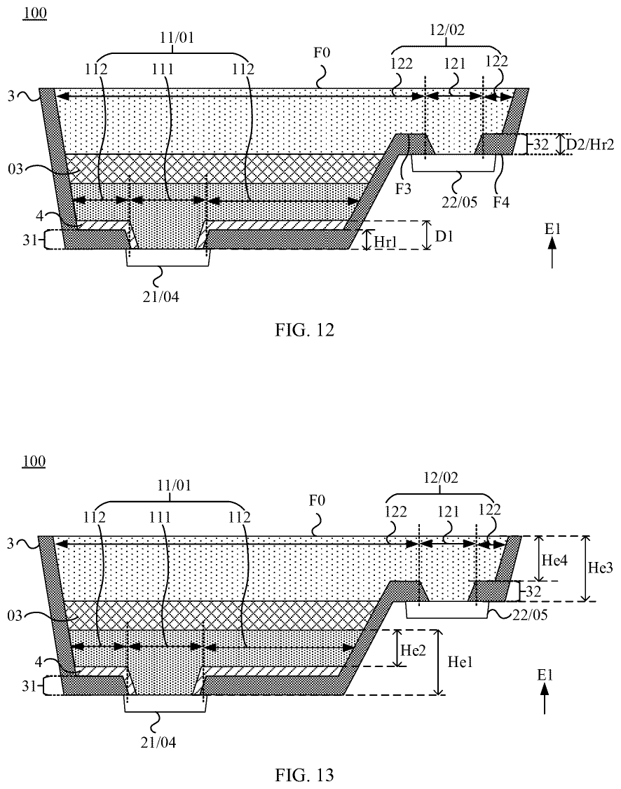

FIG. 12 is a structure diagram of another light-emitting element according to an embodiment of the present disclosure. As shown in FIG. 12, optionally, in addition to the first electrode 11 and the first connection electrode 21, the light-emitting element 100 further includes a second electrode 12 and a second connection electrode 22. The second electrode 12 is connected to the second connection electrode 22 and receives a signal through the second connection electrode 22. At least a part of the region of the reflective layer 3 is located on one side, facing away from the light emission surface F0, of the second electrode 12. In addition to the first reflective region 31, the reflective layer 3 further includes a second reflective region 32. The second reflective region 32 and the second connection electrode 22 are located on the same side of the second electrode 12. The second reflective region 32 is located between the layer in which the second electrode 12 is located and the layer in which the second connection electrode 22 is located. The second electrode 12 includes a third region 121 and a fourth region 122. The third region 121 is connected to the second connection electrode 22, and the spacing between the fourth region 122 and the layer in which the second connection electrode 22 is located in the first direction E1 is D2, where D2>0.

For example, FIG. 12 is illustrated by using an example in which the first electrode 11 is the P electrode 01, the second electrode 12 is the N electrode 02, the first connection electrode 21 is the P connection electrode 04, and the second connection electrode 22 is the N connection electrode 05. As shown in FIG. 12, to achieve the electrical connection between the N electrode 02 and the N connection electrode 05, a part of the P electrode 01 and a part of the light-emitting layer 03 need to be removed to expose a part of the N electrode 02, and the N electrode 02 is electrically connected to the N connection electrode 05 through the exposed N electrode 02. When the second electrode 12 is the N electrode 02, the second reflective region 32 can be understood as a part of the reflective layer 3 that is disposed corresponding to the exposed part of the N electrode, the second reflective region 32 and the second connection electrode 22 are both located on one side, facing away from the light emission surface F0, of the second electrode 12, and thus, the light in this region can be reflected through the second reflective region 32, thereby improving the light emission efficiency of the light-emitting element.

With reference to the design concept of the first reflective region 31 described above, in an embodiment, by setting the spacing D2 between the fourth region 122 of the second electrode 12 and the layer in which the second connection electrode 22 is located in the first direction E1 to meet the condition of D2>0, a gap with a height of D2 can be formed between the fourth region 122 of the second electrode 12 and the layer in which the second connection electrode 22 is located. In this manner, the space where the gap is located can be used to accommodate the second reflective region 32 of at least the partial thickness, thereby reducing the pressure on the second connection electrode 22 from the second reflective region 32 to a certain extent, reducing the risk of the peeling of the second connection electrode 22, ensuring the reliable connection between the second connection electrode 22 and the second electrode 12, and further improving the product reliability.

With reference to FIG. 12, optionally, the voltage value of the signal received by the first electrode 11 is greater than the voltage value of the signal received by the second electrode 12, where D1>D2, that is, the spacing D1 between the layer in which the second region 112 of the first electrode 11 is located and the layer in which the first connection electrode 21 is located is greater than the spacing D2 between the layer in which the fourth region 122 of the second electrode 12 is located and the layer in which the second connection electrode 22 is located.

In an embodiment, with reference to FIG. 12, when the voltage value of the signal received by the first electrode 11 is greater than the voltage value of the signal received by the second electrode 12, the first electrode 11 is the P electrode 01, the first connection electrode 21 is the P connection electrode 04, the second electrode 12 is the N electrode 02, and the second connection electrode 22 is the N connection electrode 05. Since the electrons flow into the P electrode 01 more difficultly than flowing out of the N electrode 02 according to the flow direction of currents, the P electrode 01 is generally provided with a current spreading layer 4 so that the P electrode 01 can receive an electric signal more easily, whereas the N electrode 02 may generally not be provided with any current spreading layer. Therefore, when the first electrode 11 is the P electrode 01 and the second electrode 12 is the N electrode 02, the gap between the layer in which the second region 112 of the first electrode 11 is located and the layer in which the first connection electrode 21 is located generally needs to accommodate both the current spreading layer 4 and the reflective layer 3, the gap between the layer in which the fourth region 122 of the second electrode 12 is located and the layer in which the second connection electrode 22 is located only needs to accommodate the reflective layer 3, and thus, D1 may be set to be greater than D2, thereby ensuring the reliable connection between the electrodes.

Certainly, the case described above is only a general case. In some special cases, D1≤D2 is optional according to different design requirements. For example, when the thickness of the first reflective region 31 is less than the thickness of the second reflective region 32, a case of D1≤D2 may exist. It is to be noted that for such special cases, the embodiments of the present disclosure do not limit the corresponding relationship from the first electrode 11 and the second electrode 12 to the P electrode 01 and the N electrode 02. For example, the first electrode 11 is the P electrode 01 and the second electrode 12 is the N electrode 02; or the first electrode 11 is the N electrode 02 and the second electrode 12 is the P electrode 01.

With continued reference to FIG. 12, the thickness of the second reflective region 32 in the first direction E1 is Hr2. Optionally, D2≥Hr2. With reference to the design concept of the first reflective region 31 described above, in this embodiment, by setting D2≥Hr2, that is, by setting the gap between the fourth region 122 of the second electrode 12 and the second connection electrode 22 to be greater than or equal to the thickness of the second reflective region 32, the second reflective region 32 can be completely accommodated in the gap between the fourth region 122 of the second electrode 12 and the second connection electrode 22. In this manner, the second connection electrode 22 can be prevented from being pressed by the second reflective region 32 and thermally expanded freely without the risk of peeling, thereby ensuring the reliable connection between the second electrode 12 and the second connection electrode 22.

It is to be noted that FIG. 12 is illustrated by using an example of D2=Hr2, and the above setting is non-limiting. In other embodiments, D2 may also be set to be greater than Hr2, as long as the gap between the fourth region 122 of the second electrode 12 and the second connection electrode 22 is sufficient to accommodate the second reflective region 32 of the full thickness.

With reference to FIG. 12, in one embodiment, optionally, Hr1=Hr2, that is, the thickness of the first reflective region 31 is equal to the thickness of the second reflective region 32. Through such a setting, the thickness of the reflective layer 3 in different regions can be kept consistent, thereby reducing the complexity of the preparation process.

In other embodiments, when the reflective layer 3 adopts the Bragg reflective layer design, the following case may exist: the region where one of the electrodes (one of the P electrode 01 or the N electrode 02) is located receives more light transmitted towards the light nonemission side, and the reflective layer corresponding to this region plays a larger reflection role; the region where the other electrode (the other of the P electrode 01 and the N electrode 02) is located receives less light transmitted towards the light nonemission side, the reflective layer corresponding to this region plays a smaller reflection role or even does not need to play a reflection role, or the space in the region where the electrode is located for setting the reflective layer is limited. In this case, optionally, the thicknesses of the first reflective region 31 may be set to be not equal to the thicknesses of the second reflective region 32 (that is, Hr1≠Hr2).

For example, with reference to FIG. 12, optionally, the voltage value of the signal received by the first electrode 11 is greater than the voltage value of the signal received by the second electrode 12, where Hr1>Hr2.

As described above, when the voltage value of the signal received by the first electrode 11 is greater than the voltage value of the signal received by the second electrode 12, the first electrode 11 is the P electrode 01, and the second electrode 12 is the N electrode 02.

For example, FIG. 12 is illustrated by using an example in which the P electrode 01 (the first electrode 11) receives more light transmitted towards the light nonemission side than the N electrode 02 (the second electrode 12), and in this case, the thickness of the reflective layer (that is, the first reflective region 31) at the P electrode 01 may be set to be greater than the thickness of the reflective layer (that is, the second reflective region 32) at the N electrode 02, thereby ensuring the light emission efficiency.

Certainly, the above setting is only illustrative and not limiting. With reference to FIG. 12, in other embodiments, when the voltage value of the signal received by the first electrode 11 is greater than the voltage value of the signal received by the second electrode 12, Hr1 may also be set to be less than Hr2, thereby meeting different design requirements.

With reference to FIG. 12, optionally, the second reflective region 32 includes a third surface F3 and a fourth surface F4. The third surface F3 is in contact with the fourth region 122 of the second electrode 12, and the fourth surface F4 is in contact with the second connection electrode 22. In this case, only the reflective layer 3 is included in the gap between the second electrode 12 and the second connection electrode 22. For example, since the N electrode 02 generally is not provided with any current spreading layer, optionally, only the reflective layer 3 is included in the gap between the second electrode 12 and the second connection electrode 22 when the second electrode 12 is the N electrode 02. In this case, the third surface F3 of the second reflective region 32 of the reflective layer 3 is in contact with the fourth region 122 of the second electrode 12, and the fourth surface F4 is in contact with the second connection electrode 22.

With reference to FIG. 12, optionally, at least one side surface of the second reflective region 32 is in contact with the third region 121 of the second electrode 12. With reference to the design concept of the first reflective region 31 described above, in this embodiment, by setting at least one side surface of the second reflective region 32 to be in contact with the third region 121 of the second electrode 12 and for example by setting at least one side surface of the second reflective region 32 to be in contact with the protrusion portion in the third region 121, the reflective layer 3 can be disposed as much as possible on one side, facing away from the light emission surface F0, of the light-emitting element to enable the reflective layer 3 to sufficiently reflect the light and avoid the light leaking out from the side facing away from the light emission surface F0, thereby improving the light emission efficiency of the light-emitting element.

FIG. 13 is a structure diagram of another light-emitting element according to an embodiment of the present disclosure. As shown in FIG. 13, optionally, the thickness of the third region 121 in the first direction E1 is He3, and the thickness of the fourth region 122 in the first direction E1 is He4, where He3>He4. In an embodiment, to achieve the electrical connection between the second electrode 12 and the second connection electrode 22 and form the accommodating space for the second reflective region 32, the third region 121 of the second electrode 12 protrudes towards the second connection electrode 22 as compared to the fourth region 122, and thus, the thickness He3 of the third region 121 of the second electrode 12 is greater than the thickness He4 of the fourth region 122 of the second electrode 12.

With reference to FIG. 13, in one embodiment, optionally, He1=He3 and/or He2=He4. For example, by setting the thicker part (that is, the first region 111) of the first electrode 11 and the thicker part (that is, the third region 121) of the second electrode 12 to have the same thickness (He1=He3) and/or by setting the thinner part (that is, the second region 112) of the first electrode 11 and the thinner part (that is, the fourth region 122) of the second electrode 12 to have the same thickness (He2=He4), different electrodes can be designed uniformly, thereby simplifying the process.

With reference to FIG. 13, in other embodiments, optionally, He1≠He3 and/or He2≠He4. For example, by setting the thicker part (that is, the first region 111) of the first electrode 11 and the thicker part (that is, the third region 121) of the second electrode 12 to have different thicknesses (He1≠He3) and/or by setting the thinner part (that is, the second region 112) of the first electrode 11 and the thinner part (that is, the fourth region 122) of the second electrode 12 to have different thicknesses (He2≠He4), at least one of the thicker region or the thinner region in the first electrode 11 and the second electrode 12 can be differently designed, thereby adapting to the different polarities and the different materials of the first electrode 11 and the second electrode 12 and meeting a variety of different design requirements.

For example, with reference to FIG. 13, as a feasible implementation, optionally, the voltage value of the signal received by the first electrode 11 is greater than the voltage value of the signal received by the second electrode 12, where Hr1>Hr3 and/or Hr2>Hr4. As described above, when the voltage value of the signal received by the first electrode 11 is greater than the voltage value of the signal received by the second electrode 12, the first electrode 11 is the P electrode 01, and the second electrode 12 is the N electrode 02. In this embodiment, by setting the thickness Hel of the first region 111 of the first electrode 11 to be greater than the thickness He3 of the third region 121 of the second electrode 12 and/or by setting the thickness He2 of the second region 112 of the first electrode 1 to be greater than the thickness He4 of the fourth region 122 of the second electrode 12, the thickness of the P electrode 01 can be overall greater than the thickness of the N electrode 02, thereby enabling the P electrode 01 to successfully receive the electric signal.

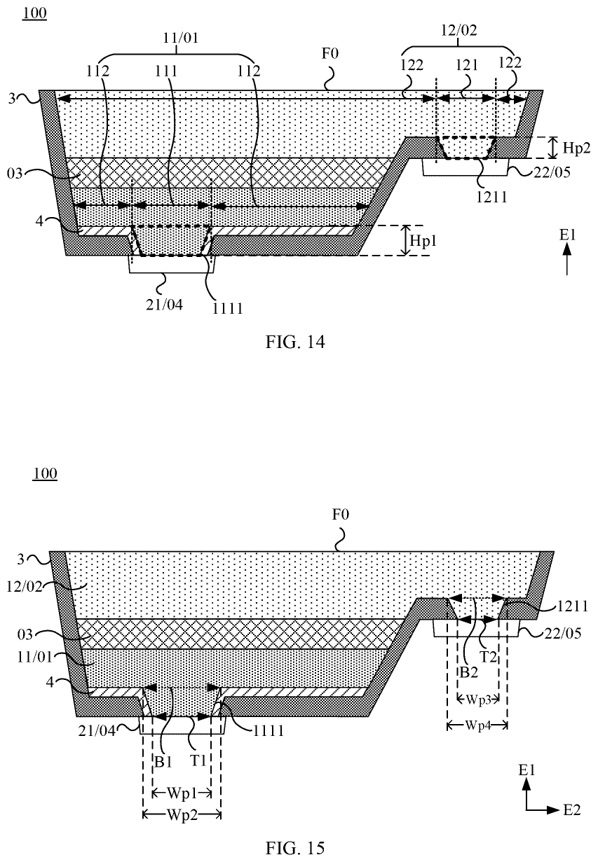

FIG. 14 is a structure diagram of another light-emitting element according to an embodiment of the present disclosure. As shown in FIG. 14, the first region 111 includes a first protrusion 1111. The first protrusion 1111 is located on one side, facing the first connection electrode 21, of the first region 111, and the thickness of the first protrusion 1111 in the first direction E1 is Hp1. The third region 121 includes a second protrusion 1211. The second protrusion 1211 is located on one side, facing the second connection electrode 22, of the third region 121, and the thickness of the second protrusion 1211 in the first direction E1 is Hp2. Optionally, Hp1≥Hp2.

As described above, the first protrusion 1111 refers to a part of the first region 111 that protrudes towards the first connection electrode 21 as compared to the second region 112, and similarly, the second protrusion 1211 refers to a part of the third region 121 that protrudes towards the second connection electrode 22 as compared to the fourth region 122. In this embodiment, by setting the first region 111 of the first electrode 11 to have the first protrusion 1111, in one aspect, the electrical connection between the first electrode 11 and the first connection electrode 21 can be achieved, and in another aspect, a gap can be formed between the second region 112 and the first connection electrode 21. Similarly, by setting the third region 121 of the second electrode 12 to have the second protrusion 1211, in one aspect, the electrical connection between the second electrode 12 and the second connection electrode 22 can be achieved, and in another aspect, a gap can be formed between the fourth region 122 and the second connection electrode 22. In this manner, layers such as the reflective layer can be accommodated in the space where these gaps are located, thereby solving the problem of the peeling of the first connection electrode 21 and the second connection electrode 22. The thickness of the first protrusion 1111 and the thickness of the second protrusion 1112 may be differently designed to achieve the personalized design of the P electrode and the N electrode, thereby meeting different design requirements.

For example, when the first electrode 11 is the P electrode 01 and the second electrode 12 is the N electrode 02, considering that the P electrode 01 is generally provided with the current spreading layer 4 to improve the conductivity property, optionally, the thickness Hp1 of the first protrusion 1111 may be set to be greater than or equal to the thickness Hp2 of the second protrusion 1211 so that the gap between the second region 112 of the first electrode 11 and the first connection electrode 21 can accommodate both the current spreading layer 4 and the reflective layer 3, thereby effectively avoiding the peeling of the first connection electrode 21.

FIG. 15 is a structure diagram of another light-emitting element according to an embodiment of the present disclosure. As shown in FIG. 15, optionally, the width of the first protrusion 1111 is greater than or equal to the width of the second protrusion 1211 in the second direction E2, where the second direction E2 is perpendicular to the first direction E1.

The width of the first protrusion 1111 being greater than or equal to the width of the second protrusion 1211 may be understood to mean that the width of the first protrusion 1111 is overall greater than or equal to the width of the second protrusion 1211. For example, the width of the first protrusion 1111 in the second direction E2 may be the maximum width that the first protrusion 1111 has in the second direction E2, the width of the second protrusion 1211 in the second direction E2 may accordingly be the maximum width that the second protrusion 1211 has in the second direction E2, and the maximum width of the first protrusion 1111 is greater than or equal to the maximum width of the second protrusion 1211 in the second direction E2. When the first electrode 11 is the P electrode 01 and the second electrode 12 is the N electrode 02, by setting the width of the first protrusion 1111 to be greater than or equal to the width of the second protrusion 1211, the P electrode can be enabled to successfully receive the electric signal.

With reference to FIG. 15, optionally, the first protrusion 1111 includes a first top portion T1 and a first bottom portion B1. The first top portion T1 is in contact with the first connection electrode 21. The width of the first top portion T1 in the second direction E2 is Wp1, and the width of the first bottom portion B1 in the second direction E2 is Wp2, where the second direction E2 is perpendicular to the first direction E1. The second protrusion 1211 includes a second top portion T2 and a second bottom portion B2. The second top portion T2 is in contact with the second connection electrode 22. The width of the second top portion T2 in the second direction E2 is Wp3, and the width of the second bottom portion B2 in the second direction E2 is Wp4, where Wp1≠Wp3 and/or Wp2≠Wp4. In an embodiment, by setting Wp1≠Wp3 and/or Wp2≠Wp4, the width of the first top portion T1 of the first protrusion 1111 and the width of the second top portion T2 of the second protrusion 1211 can be differently designed and/or the width of the first bottom B1 of the first protrusion 1111 and the width of the second bottom B2 of the second protrusion 1211 can be differently designed to achieve the personalized designs of the P electrode and the N electrode, thereby meeting a variety of different design requirements.

With reference to FIG. 15, as a feasible implementation, optionally, the voltage value of the signal received by the first electrode 11 is greater than the voltage value of the signal received by the second electrode 12, where Wp1>Wp3 and/or Wp2>Wp4. As described above, when the voltage value of the signal received by the first electrode 11 is greater than the voltage value of the signal received by the second electrode 12, the first electrode 11 is the P electrode 01, and the second electrode 12 is the N electrode 02. In this embodiment, by setting the width Wp1 of the first top portion T1 of the first protrusion 1111 to be greater than the width Wp3 of the second top portion T2 of the second protrusion 1211 and/or by setting the width Wp2 of the first bottom portion B1 of the first protrusion 1111 to be greater than the width Wp4 of the second bottom portion B2 of the second protrusion 1211, the size of the first protrusion 1111 in the second direction E2 can be greater than the size of the second protrusion 1211 in the second direction E2, thereby enabling the P electrode to successfully receive the electric signal.

In summary, the core idea of the above embodiment is to set the first electrode 11 to have a protrusion facing the corresponding first connection electrode 21 and similarly, to set the second electrode 12 to have a protrusion facing the corresponding second connection electrode 22. In this manner, the accommodating space for the reflective layer 3 can be formed while ensuring the electrical connection between the first electrode 11 and the first connection electrode 21 and the electrical connection between the second electrode 12 and the second connection electrode 22, thereby solving the problem of the peeling of the first connection electrode 21 and the second connection electrode 22 and ensuring the reliable connection between the electrodes.

Another two design schemes for solving the peeling of the connection electrode (the first connection electrode 21 and/or the second connection electrode 22) will be provided below by using an example in which the light-emitting element 100 includes a first electrode 11, a second electrode 12, a reflective layer 3, a first connection electrode 21 and a second connection electrode 22, at least a part of the region of the reflective layer 3 is located on one side, facing away from the light emission surface F0, of the first electrode 11, at least a part of the region of the reflective layer 3 is located on one side, facing away from the light emission surface F0, of the second electrode 12, the reflective layer 3 includes a first reflective region 31 and a second reflective region 32, the first reflective region 31 and the first connection electrode 21 are located on the same side of the first electrode 11, and the second reflective region 32 and the second connection electrode 22 are located on the same side of the second electrode 12.

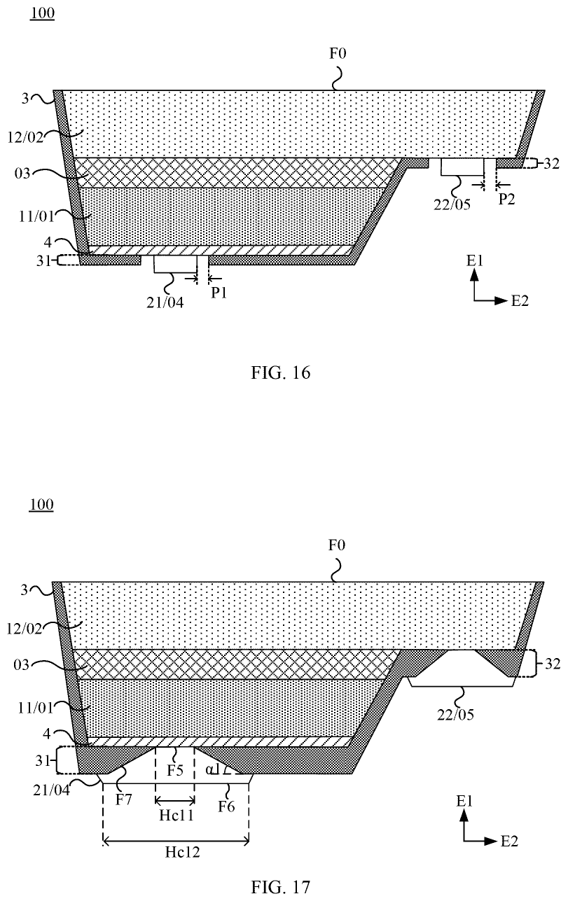

FIG. 16 is a structure diagram of another light-emitting element according to an embodiment of the present disclosure. As shown in FIG. 16, as another feasible scheme, optionally, the first reflective region 31 does not overlap the first connection electrode 21 in the first direction E1, where the first direction E1 is a direction perpendicular to the surface of the light-emitting element. Through the above setting, a certain spacing can be formed between the first reflective region 31 and the first connection electrode 21 so that when the first connection electrode 21 is thermally expanded, the first connection electrode 21 can be prevented from peeling due to the pressure from the first reflective region 31, thereby ensuring the reliable connection between the first connection electrode 21 and the first electrode 11.

As shown in FIG. 16, optionally, a first spacing PI exists between the first reflective region 31 and the first connection electrode 21 in the second direction E2, where P1>0, and the second direction E2 is perpendicular to the first direction E1. It is to be noted that the specific value of the first spacing can be set freely, which is not limited in the embodiments of the present disclosure. In addition, the spacings between the first connection electrode 21 and the first reflective region 31 in any different directions parallel to the light emission surface F0 may be equal or unequal, which is not limited in the embodiments of the present disclosure either.

As shown in FIG. 16, similarly, optionally, the second reflective region 32 does not overlap the second connection electrode 22 in the first direction E1. Through the above setting, a certain spacing can be formed between the second reflective region 32 and the second connection electrode 22 so that when the second connection electrode 22 is thermally expanded, the second connection electrode 22 can be prevented from peeling due to the pressure from the second reflective region 32, thereby ensuring the reliable connection between the second connection electrode 22 and the second electrode 12.

With reference to FIG. 16, a first spacing P1 exists between the first reflective region 31 and the first connection electrode 21 in the second direction E2, where P1>0; a second spacing P2 exists between the second reflective region 32 and the second connection electrode 22 in the second direction E2, wherein P2>0; where the second direction E2 is perpendicular to the first direction E1. Optionally, P1=P2 or P1≠P2.

For example,, the first spacing PI between the first reflective region 31 and the first connection electrode 21 and the second spacing P2 between the second reflective region 32 and the second connection electrode 22 may be of the same design. By setting P1=P2, the process complexity can be reduced, thereby simplifying the preparation process.

In addition, in other embodiments, since the sizes and properties of the first electrode 11, the second electrode 12 and their respective corresponding connection electrodes (that is, the first connection electrode 21 and the second connection electrode 22) may inherently differ from each other, the first spacing P1 and the second spacing P2 can be differently designed, thereby better alleviating the pressure.

With reference to FIG. 16, in one embodiment, optionally, the first electrode 11 is located on one side, facing away from the light emission surface F0, of the second electrode 12, where P1<P2.

In an embodiment, when the first electrode 11 is located on one side, facing away from the light emission surface F0, of the second electrode 12, the first electrode 11 away from the light emission surface F0 more than the second electrode 12. In this case, compared to the reflective layer (that is, the second reflective region 32) disposed on one side, facing away from the light emission surface F0, of the second electrode 12, the reflective layer (that is, the first reflective region 31) disposed on one side, facing away from the light emission surface F0, of the first electrode 11 needs to play a larger reflection role. In this embodiment, since the first spacing P1 exists between the first reflective region 31 and the first connection electrode 21 and the second spacing P2 exists between the second reflective region 32 and the second connection electrode 22, a light leak may occur in the regions where the first spacing and the second spacing are located, thereby affecting the light emission efficiency. To solve the above problem, in this embodiment, by setting P1<P2, the light incident from the region where the first spacing that is smaller is located to the light nonemission side can be reduced or even avoided while ensuring the reliable connection between the first electrode 11 and the first connection electrode 21, thereby ensuring the reflection effect of the first reflective region 31 on the light and ensuring the light emission efficiency of the light-emitting element. Since the second reflective region 32 needs to perform small reflection function or may even perform no reflection function, the second spacing between the second reflective region 32 and the second connection electrode 22 may be larger, thereby effectively avoiding the peeling of the second connection electrode 22 and ensuring the reliable connection of the second connection electrode 22 and the second electrode 12.

Certainly, the above setting is not the only one. When the first electrode 11 is located on one side, facing away from the light emission surface F0, of the second electrode 12, PI may be set to be greater than P2 in some special cases. For example, if another layer that has a reflection effect on light is disposed on the side, facing away from the light emission surface F0, of the first connection electrode 21, the requirement for the first reflective region 31 to play a reflection role is reduced, and in this case, P1 may be set to be greater than P2.

FIG. 17 is a structure diagram of another light-emitting element according to an embodiment of the present disclosure. As shown in FIG. 17, as another feasible scheme, optionally, the first reflective region 31 partially overlaps the first connection electrode 21 in the first direction E1, where the first direction E1 is a direction perpendicular to the surface of the light-emitting element. In combination with the above description, through the above setting, at least a part of the first connection electrode 21 can be located on the side, facing away from the first electrode 11, of the first reflective region 31. In one aspect, the degree of pressure on the first connection electrode 21 from the first reflective region 31 can be reduced when the first connection electrode 21 is thermally expanded, thereby reducing or even eliminating the peeling of the first connection electrode 21 and ensuring the reliable connection between the first electrode 11 and the first connection electrode 21. In another aspect, since the first reflective region 31 is located between the layer in which the first electrode 11 is located and the layer in which the first connection electrode 21 is located, by setting the first reflective region 31 to partially overlap the first connection electrode 21 in the first direction E1, the first reflective region 31 can be enabled to cover the light nonemission surface of the light-emitting element as much as possible to ensure the reflection effect of the first reflective region 31 on the light, thereby ensuring high light emission efficiency.

As shown in FIG. 17, optionally, the first connection electrode 21 includes a first top surface F5 and a second top surface F6. The first top surface F5 is located on one side, facing the first electrode 11, of the second top surface F6. The width of the first top surface F5 in the second direction E2 is Hc11, and the width of the second top surface F6 in the second direction E2 is Hc12, where the second direction E2 is perpendicular to the first direction E1 and Hc11<Hc12.

With reference to FIG. 17, the first top surface F5 and the second top surface F6 may be understood as two surfaces of the first connection electrode 21 opposite to each other in the first direction E1, where the first top surface F5 is located on one side, facing the first electrode 11, of the second top surface F6. In this embodiment, by setting the width Hc11 of the first top surface F5 in the second direction E2 to be less than the width Hc12 of the second top surface F6 in the second direction E2, the section shape of the first connection electrode 21 on a cross-section perpendicular to the light emission surface F0 is trapezoid-like to form an inclined side surface, and the width of the first connection electrode 21 between the two opposite side surfaces in the second direction E2 is gradually increasing in the direction of the first electrode 11 pointing towards the first connection electrode 21. In this manner, when the side surface of the first reflective region 31 is in contact with the side surface of the first connection electrode 21, the degree of pressure on the first connection electrode 21 from the first reflective region 31 can be reduced, thereby reducing or even eliminating the peeling of the first connection electrode 21 and ensuring the reliable connection between the first electrode 11 and the first connection electrode 21.

As shown in FIG. 17, optionally, the first connection electrode 21 includes a first side surface F7 that connects the first top surface F5 with the second top surface F6, and the included angle between at least a part of the region of the first side surface F7 and the second top surface F6 is α1, where α1<90°.

In an embodiment, assuming that the included angle between the first side surface F7 and the second top surface F6 is 90°, the pressure on the first connection electrode 21 from the first reflective region 31 when the first connection electrode 21 is thermally expanded is f. In this embodiment, by setting the width Hc11 of the first top surface F5 in the second direction E2 to be less than the width Hc12 of the second top surface F6 in the second direction E2, the first side surface F7 that is inclined is formed, and the included angle α1 between at least a part of the region of the first side surface F7 and the second top surface F6 is less than 90°. The pressure on the first connection electrode 21 from the first reflective region 31 when the first connection electrode 21 is thermally expanded is f1, f1=f·sinα1, and since α1<90°, f1<f. In this manner, the degree of pressure on the first connection electrode 21 from the first reflective region 31 can be reduced, thereby reducing the peeling of the first connection electrode 21 and ensuring the reliable connection between the first electrode 11 and the first connection electrode 21.

According to the above explanation, the smaller the included angle between the first side surface F7 and the second top surface F6, the smaller the pressure on the first connection electrode 21 from the first reflective region 31 when the first connection electrode 21 is thermally expanded. Therefore, with reference to FIG. 17, optionally, α1≤30° to minimize the degree of incline of the first side surface F7, and thus, the first connection electrode 21 gains more expansion space when the first connection electrode 21 is thermally expanded, thereby reducing the pressure on the first connection electrode 21 from the first reflection region 31.

With reference to FIG. 17, when the reflective layer 3 includes the second reflective region 32, the structure of the second connection electrode 22 may be designed as same as the structure of the first connection electrode 21 to reduce the pressure on the second connection electrode 22 from the second reflective region 32. The details are not repeated here. It is to be noted that the setting parameters of the second connection electrode 22 and the setting parameters of the first connection electrode 21 may be the same or may be differently designed according to actual requirements, which is not limited in the embodiments of the present disclosure.

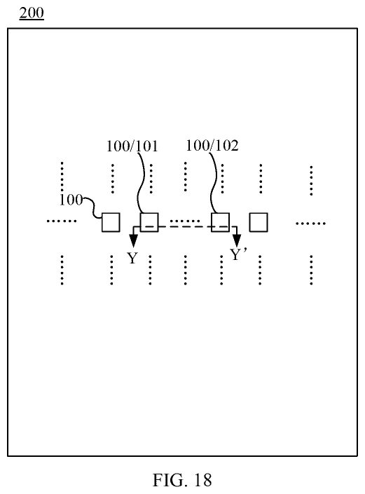

In summary, the above embodiments give a detailed description of the structure of the light-emitting element. Based on the same inventive concept, the embodiments of the present disclosure further provide a display panel. For example, FIG. 18 is a structure diagram of a display panel according to an embodiment of the present disclosure. As shown in FIG. 18, the display panel 200 includes the light-emitting element 100 provided by any of the embodiments described above, and thus, the display panel has the same beneficial effects as the above light-emitting element. For similarities, reference may be made to the descriptions in the preceding embodiments of the light-emitting element. The details are not repeated here.

For example, the light-emitting element 100 may be a micro-LED, the display panel may accordingly be a micro-LED display panel in this embodiment, and the light-emitting element 100 is provided corresponding to the sub-pixels in the display panel 200. For example, the display panel 200 may include multiple red sub-pixels, multiple green sub-pixels and multiple blue sub-pixels, and each sub-pixel corresponds to a light-emitting element of a corresponding emitted color.

For example, as shown in FIG. 18, the display panel 200 includes a first light-emitting element 101 and a second light-emitting element 102. The terms “first” and “second” do not have substantive meanings and are only used for distinction purposes. In an embodiment, the first light-emitting element 101 and the second light-emitting element 102 may differ from each other in emitted color or location.

In this embodiment, optionally, the wavelength of light emitted by the first light-emitting element 101 is λ1, and the wavelength of light emitted by the second light-emitting element 102 is λ2, where λ1≠λ2; for example, λ1>λ2. In an embodiment, since the wavelength of the light emitted by the first light-emitting element 101 is different from the wavelength of the light emitted by the second light-emitting element 102, the emitted color of the first light-emitting element 101 is different from the emitted color of the second light-emitting element 102. For example, when λ1>λ2, the first light-emitting element 101 may be a red light-emitting element, and the second light-emitting element 102 may be a green light-emitting element or a blue light-emitting element; or the first light-emitting element 101 is a green light-emitting element, and the second light-emitting element 102 is a blue light-emitting element.

In other embodiments, optionally, the first light-emitting element 101 and the second light-emitting element 102 emit light of the same color. The display panel includes a first display region and a second display region, the first light-emitting element 101 is located in the first display region, and the second light-emitting element 102 is located in the second display region. The first display region and the second display region may be any two different regions in the display panel, which is not limited in the embodiments of the present disclosure.

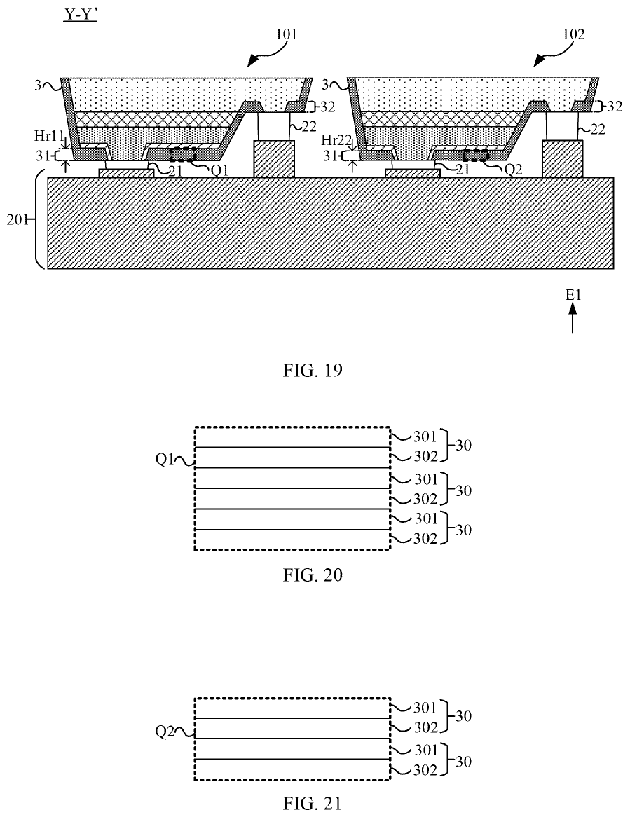

FIG. 19 is a section view of the display panel taken along YY′ in FIG. 18. As shown in FIGS. 18 and 19, the light-emitting element 100 is electrically connected to an array substrate 201 internally provided with a pixel driving circuit via the first connection electrode 21 and the second connection electrode 22, and the light-emitting element 100 is driven to emit light via the pixel driving circuit. With reference to FIGS. 18 and 19, optionally, the thickness of the first reflective region 31 of the first light-emitting element 101 in a direction (for example, the first direction E1 in FIG. 19) perpendicular to the surface of the first light-emitting element 101 is Hr11, and the thickness of the first reflective region 31 of the second light-emitting element 102 in a direction (for example, the first direction E1 in FIG. 19) perpendicular to the surface of the second light-emitting element 102 is Hr22, where Hr11>Hr22.

The first light-emitting element 101 and the second light-emitting element 102 may be light-emitting elements with different emitted colors or may be light-emitting elements which have the same emitted color but are located in different display regions, which is not limited in the embodiments of the present disclosure.

In one embodiment, when the emitted color of the first light-emitting element 101 is different from the emitted color of the second light-emitting element 102 or the wavelength λ1 of the light emitted by the first light-emitting element 101 is different from the wavelength λ2 of the light emitted by the second light-emitting element 102, optionally, the thickness of the first reflective region 31 of the first light-emitting element 101 is set to be different from the thickness of the first reflective region 31 of the second light-emitting element 102 (that is, Hr11≠Hr22). In an embodiment, for the light-emitting elements with different emitted colors, the wavelengths of the light to be reflected by the corresponding reflective layers 3 are different, and the reflective effect of the Bragg reflective layer is related to the wavelength of the incident light. Therefore, for the light-emitting elements 100 with different emitted colors, the thicknesses of the first reflective regions 31 of the reflective layers 3 of the light-emitting elements 100 in the first direction E1 can be differently designed, thereby enabling different light-emitting elements to have high light emission efficiency. For example, when the wavelength λ1 of the light emitted by the first light-emitting element 101 is greater than the wavelength 22 of the light emitted by the second light-emitting element 102, the thickness Hr11 of the first reflective region 31 of the first light-emitting element 101 may be set to be greater than the thickness Hr22 of the first reflective region 31 of the second light-emitting element 102.

In other embodiments, when the emitted color of the first light-emitting element 101 is the same as the emitted color of the second light-emitting element 102 but the first light-emitting element 101 and the second light-emitting element 102 are located in different display regions in the display panel, the thickness of the first reflective region 31 of the first light-emitting element 101 and the thickness of the first reflective region 31 of the second light-emitting element 102 may be differently set according to requirements. In an embodiment, with the development of display technology, to meet the diversified needs of users, the functions integrated into the display panel become more and more complex, and the requirements for reflectivity may be different for different display regions. Therefore, the thicknesses of the first reflective regions 31 of the reflective layers 3 of the light-emitting elements which have the same emitted color but are located in different display regions in the first direction E1 may be differently designed, thereby meeting different design requirements of different display regions. Optionally, when the display panel includes a first display region and a second display region, the first light-emitting element 101 and the second light-emitting element 102 emit light of the same color, the first light-emitting element 101 is located in the first display region and the second light-emitting element 102 is located in the second display region, the thickness Hr11 of the first reflective region 31 of the first light-emitting element 101 may be set to be different from the thickness Hr22 of the first reflective region 31 of the second light-emitting element 102. For example, when the first display region is a normal display region and the second display region is correspondingly provided with a fingerprint recognition unit, to ensure the transmittance of the second display region, the thickness of the first reflective region 31 of the second light-emitting element 102 may be set to be less than the thickness of the first reflective region 31 of the first light-emitting element 101 (that is, Hr22<Hr11).

With reference to FIG. 19, it is to be noted that whether the thickness of the second reflective region 32 of the first light-emitting element 101 and the thickness of the second reflective region 32 of the second light-emitting element 102 in the first direction E1 are differently designed may be determined according to requirements, which is not limited in the embodiments of the present disclosure.

FIG. 20 is an enlarged view of region Q1 in FIG. 19, and FIG. 21 is an enlarged view of region Q2 in FIG. 19. In conjunction with FIGS. 19 to 21, optionally, the first reflective region 31 of the first light-emitting element 101 includes N1 Bragg reflective layers 30, where N1>1; the first reflective region 31 of the second light-emitting element 102 includes N2 Bragg reflective layers 30, where N2>0; where N1>N2. As described above, in this embodiment, the first light-emitting element 101 and the second light-emitting element 102 may be light-emitting elements with different emitted colors or may be light-emitting elements which have the same emitted color but are located in different display regions.

As described above, one Bragg reflective layer 30 includes a first reflective sub-layer 301 and a second reflective sub-layer 302. The refractive index of the first reflective sub-layer 301 is different from the refractive index of the second reflective sub-layer 302 and/or the thickness of the first reflective sub-layer 301 is different from the thickness of the second reflective sub-layer 302. In this embodiment, by setting the number of Bragg reflective layers 30 included in the first reflective region 31 of the first light-emitting element 101 to be different from the number of Bragg reflective layers 30 included in the first reflective region 31 of the second light-emitting element 102, the thickness of the first reflective region 31 of the first light-emitting element 101 in the first direction E1 can be different from the thickness of the first reflective region 31 of the second light-emitting element 102 in the first direction E1, thereby achieving the different setting of the thicknesses of the reflective layers in different light-emitting elements.

For example, with an example in which the emitted color of the first light-emitting element 101 is different from the emitted color of the second light-emitting element 102, N1 may be set to be greater than N1 when the wavelength of the light emitted by the first light-emitting element 101 is greater than the wavelength of the light emitted by the second light-emitting element 102. In addition, when the emitted color of the first light-emitting element 101 is the same as the emitted color of the second light-emitting element 102 but the first light-emitting element 101 and the second light-emitting element 102 are located in different display regions, N1 may be set to be not equal to N2 according to the design requirements of the different display regions (that is, N1>N2 or N1<N2).

It is to be noted that the number of Bragg reflective layers 30 shown in FIGS. 20 and 21

is only for illustrative purposes, and the number of Bragg reflective layers included in the reflective layers of different light-emitting elements may be set freely, which is not limited to the embodiments of the present disclosure.

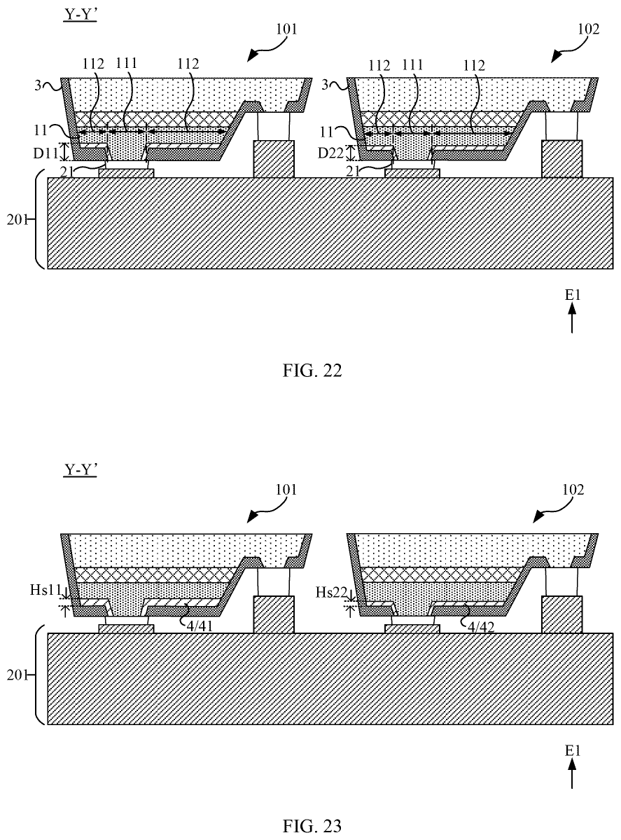

FIG. 22 is another section view of the display panel taken along YY′ in FIG. 18. As shown in FIG. 22, optionally, in the first light-emitting element 101, the spacing between layer in which the second region 112 of the first electrode 11 is located and the layer in which the first connection electrode 21 is located in a direction (for example, the first direction E1 in FIG. 22) perpendicular to the surface of the first light-emitting element is D11; in the second light-emitting element 102, the spacing between layer in which the second region 112 of the first electrode 11 is located and the layer in which the first connection electrode 21 is located in a direction (for example, the first direction E1 in FIG. 22) perpendicular to the surface of the second light-emitting element is D22; where D11>D22. As described above, in this embodiment, the first light-emitting element 101 and the second light-emitting element 102 may be light-emitting elements with different emitted colors or may be light-emitting elements which have the same emitted color but are located in different display regions.

As described above, the gap between the second region 112 of the first electrode 11 and the layer in which the first connection electrode 21 is located in the light-emitting element 100 is mainly used to accommodate the first reflective region 31 of the reflective layer 3. In this embodiment, by setting the heights of the gaps corresponding to different light-emitting elements to be different from each other, the reflective layers with different thicknesses can be adaptively accommodated. In this manner, the different design requirements of different light-emitting elements for the thickness of the reflective layer can be met, and the peeling of the first connection electrode 21 can be avoided, thereby ensuring the reliable connection between the first connection electrode 21 and the first electrode 11 of different light-emitting elements.

For example, with an example in which the emitted color of the first light-emitting element 101 is different from the emitted color of the second light-emitting element 102, D11 may be set to be greater than D12 when the wavelength of the light emitted by the first light-emitting element 101 is greater than the wavelength of the light emitted by the second light-emitting element 102. In addition, when the emitted color of the first light-emitting element 101 is the same as the emitted color of the second light-emitting element 102 but the first light-emitting element 101 and the second light-emitting element 102 are located in different display regions, D11 may be set to be not equal to D12 according to the design requirements of the different display regions (that is, D11>N2 or D11<N2).

FIG. 23 is another section view of the display panel taken along YY′ in FIG. 18. As shown in FIG. 23, optionally, the first light-emitting element 101 includes a first current spreading layer 41, and the thickness of the first current spreading layer 41 in the first direction E1 is Hs11; the second light-emitting element 102 includes a second current spreading layer 42, and the thickness of the second current spreading layer 42 in the first direction E1 is Hs22; where Hs11 Hs22. As described above, in this embodiment, the first light-emitting element 101 and the second light-emitting element 102 may be light-emitting elements with different emitted colors or may be light-emitting elements which have the same emitted color but are located in different display regions.

In one embodiment, when the emitted color of the first light-emitting element 101 is different from the emitted color of the second light-emitting element 102 or the wavelength 21 of the light emitted by the first light-emitting element 101 is different from the wavelength 22 of the light emitted by the second light-emitting element 102, optionally, the thickness of the first current spreading layer 41 in the first direction E1 is set to be different from the thickness of the second current spreading layer 42 in the first direction E1. In an embodiment, since the magnitudes of the currents received by the light-emitting elements with different emitted colors are different in the display stage of the display panel, the thicknesses of the current spreading layers in the light- emitting elements with different emitted colors may be differently set. For example, since the red light-emitting element or the green light-emitting element emits light more easily than the blue light-emitting element under the same current, to ensure the display effect, the current received by the blue light-emitting element may be set to be greater than the current received by the red light-emitting element or the green light-emitting element, and in this case, the thickness of the current spreading layer in the blue light-emitting element may be adaptively set to be greater than the thickness of the current spreading layer in the red light-emitting element or the green light-emitting element, thereby matching the requirements of different light-emitting elements for the conductivity property/signal transmission efficiency.

In other embodiments, when the emitted color of the first light-emitting element 101 is the same as the emitted color of the second light-emitting element 102 but the first light-emitting element 101 and the second light-emitting element 102 are located in different display regions in the display panel, the thickness of the first current spreading layer 41 of the first light-emitting element 101 and the thickness of the second current spreading layer 42 of the second light-emitting element 102 may be differently set according to requirements. In an embodiment, since the requirements of different display regions for signal transmission efficiency may be different, in the first direction E1, the thicknesses of the current spreading layers 4 of the light-emitting elements emitting light of the same color in different display regions may be differently designed, thereby meeting the design requirements of different display regions. Optionally, when the display panel includes a first display region and a second display region, the first light-emitting element 101 and the second light-emitting element 102 emit light of the same color, the first light-emitting element 101 is located in the first display region and the second light-emitting element 102 is located in the second display region, the thickness Hs11 of the first current spreading layer 41 of the first light-emitting element 101 may be set to be different from the thickness Hs22 of the second current spreading layer 42 of the second light-emitting element 102. For example, when the requirement of the first display region for signal transmission efficiency is greater than the requirement of the second display region for signal transmission efficiency, the thickness of the first current spreading layer 41 of the first light-emitting element 101 in the first display region may be set to be greater than the thickness of the second current spreading layer 42 of the second light-emitting element 102 in the second display region (that is, Hs11>Hs22); otherwise, when the requirement of the first display region for signal transmission efficiency is less than the requirement of the second display region for signal transmission efficiency, the thickness of the first current spreading layer 41 of the first light-emitting element 101 in the first display region may be set to be less than the thickness of the second current spreading layer 42 of the second light-emitting element 102 in the second display region (that is, Hs11<Hs22).

Optionally, Hs11>Hs22 or Hs11<Hs22. In an embodiment, the thicknesses of the current spreading layers may be set adaptively according to the difference in the emitted colors of the first light-emitting element 101 and the second light-emitting element 102 or the difference in the design requirements of the display regions in which the first light-emitting element 101 and the second light-emitting element 102 are located, which is not limited to the embodiments of the present disclosure.

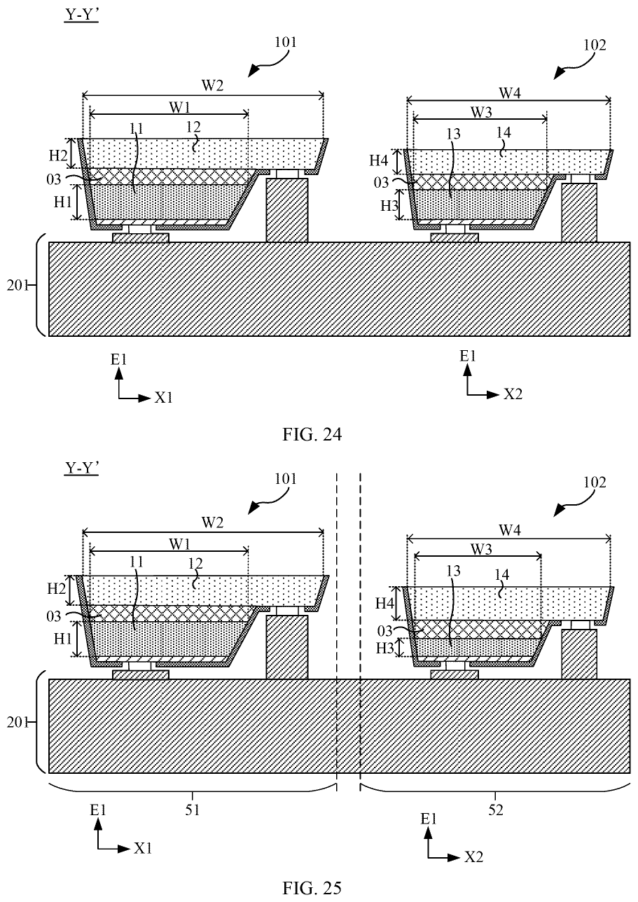

Optionally, the embodiments of the present application provide another display panel. With reference to FIG. 24 which is another section view of the display panel taken along YY′ in FIG. 18, the display panel 200 includes a first light-emitting element 101 and a second light-emitting element 102. The first light-emitting element 101 includes a first electrode 11 and a second electrode 12, the thickness of the first electrode 11 in a direction (for example, the first direction E1 in FIG. 24) perpendicular to the surface of the first light-emitting element 101 is H1, and the thickness of the second electrode 12 in the direction (for example, the first direction E1 in FIG. 24) perpendicular to the surface of the first light-emitting element 101 is H2; the second light-emitting element 102 includes a third electrode 13 and a fourth electrode 14, the thickness of the third electrode 13 in a direction perpendicular to the surface of the second light-emitting element 102 is H3, and the thickness of the fourth electrode 14 in a direction perpendicular to the surface of the second light-emitting element 102 is H4; where H1≠H2 and/or H3≠H4.

Since a light-emitting element generally includes a positive electrode (P electrode) and a negative electrode (N electrode), optionally, in this embodiment, one of the first electrode 11 or the second electrode 12 is a P electrode and the other is an N electrode; and/or, one of the third electrode 13 or the fourth electrode 14 is a P electrode and the other is an N electrode. The positive electrode is used for receiving a high-level signal to provide a positive signal for the light-emitting layer of the light-emitting element, and the negative electrode is used for receiving a low-level signal to provide a negative signal for the light-emitting layer of the light-emitting element. Since the positive electrode and the negative electrode each have a different material and serve a different function, the requirements of the light-emitting element for the area or size of the positive electrode and the negative electrode are not completely consistent. Therefore, in the present application, by setting the first electrode 11 and the second electrode 12 in the first light-emitting element 101 to have different thicknesses and/or by setting the third electrode 13 and the fourth electrode 14 in the second light-emitting element 102 to have different thicknesses, the respective thicknesses of the P electrode and the N electrode are independently set, thereby better meeting the requirements of the light-emitting element for the size and performance of different electrodes.

Optionally, in this embodiment, the first light-emitting element 101 and the second light-emitting element 102 are any two of a red light-emitting element, a green light-emitting element or a blue light-emitting element, that is, the first light-emitting element 101 and the second light-emitting element 102 are two light-emitting elements that emit light of different colors. For example, the first light-emitting element 101 is a red light-emitting element and the second light-emitting element 102 is a green light-emitting element, the first light-emitting element 101 is a red light-emitting element and the second light-emitting element 102 is a blue light-emitting element, the first light-emitting element 101 is a blue light-emitting element and the second light-emitting element 102 is a green light-emitting element, the first light-emitting element 101 is a green light-emitting element and the second light-emitting element 102 is a red light-emitting element, the first light-emitting element 101 is a green light-emitting element and the second light-emitting element 102 is a blue light-emitting element, or the first light-emitting element 101 is a blue light-emitting element and the second light-emitting element 102 is a red light-emitting element.

Optionally, in this embodiment, with reference to FIG. 25 which is another section view of the display panel taken along YY′ in FIG. 18, the first light-emitting element 101 and the second light-emitting element 102 may be light-emitting elements with the same emitted color, and the display panel 200 may include a first display region 51 and a second display region 52. The first light-emitting element 101 is located in the first display region 51, and the second light-emitting element 102 is located in the second display region 52, that is, the first light-emitting element 101 and the second light-emitting element 102 are located in different display regions.

Optionally, in this embodiment, |H1−H2|≠|H3−H4|, that is, the thickness difference between the first electrode 11 and the second electrode 12 in the first light-emitting element 101 is different from the thickness difference between the third electrode 13 and the fourth electrode 14 in the second light-emitting element 102.

When the emitted colors of the first light-emitting element 101 and the second light-emitting element 102 are different from each other, the light-emitting elements with different emitted colors may have different electrode materials, different light emission efficiency or different light-emitting areas, and thus, the electrode sizes of the light-emitting elements with different emitted colors need to be differently designed, thereby better matching the requirements of the light-emitting elements with different colors. Therefore, in this embodiment, it may be set that |H1−H2|≠|H3−H4|.

When the first light-emitting element 101 and the second light-emitting element 102 have the same emitted color but are located in different display regions, since the display panel may have different display regions integrated with different functions, such as a normal display region and an under-display camera region, or two display regions with different data refresh frequencies, to match the different functions of different display regions, even if the first light-emitting element 101 and the second light-emitting element 102 have the same emitted color, the respective electrode sizes and electrode areas of the light-emitting elements may also need to be independently designed. In this case, it may also be set that |H1−H2|≠|H3−H4|.

Optionally, in this embodiment, the voltage value of the signal received by the first electrode 11 is greater than the voltage value of the signal received by the second electrode 12, that is, the first electrode 11 is a P electrode and the second electrode 12 is an N electrode. The voltage value of the signal received by the third electrode 13 is greater than the voltage value of the signal received by the fourth electrode 14, that is, the third electrode 13 is a P electrode and the fourth electrode 14 is an N electrode.

In this case, in an optional implementation, H1>H2 and/or H3>H4, that is, the thickness of the P electrode is greater than the thickness of the N electrode in the first light-emitting element 101 and/or the thickness of the P electrode is greater than the thickness of the N electrode in the second light-emitting element 102.

Since the P electrode is used for providing a positive signal for the light-emitting element and the N electrode is used for providing a negative signal for the light-emitting element, generally, the migration of the positive signal (that is, hole carriers) is more difficult than the migration of the negative signal (that is, electrons). Therefore, to balance the transmission rates of the positive and negative signals, in this embodiment, the thickness of the P electrode is set to be greater than the thickness of the N electrode.

For example, (H1−H2|>|H3−H4|, that is, the thickness difference between the P electrode and the N electrode in the first light-emitting element 101 is greater than the thickness difference between the P electrode and the N electrode in the second light-emitting element 102. As described above, the emitted color of the first light-emitting element 101 is different from the emitted color of the second light-emitting element 102 or the first light-emitting element 101 and the second light-emitting element 102 are located in different display regions, and thus, the light emission requirements for the two light-emitting elements may be different. To match the different light emission requirements, it is set that |H1−H2|>|H3−H4|, thereby independently adjusting the electrode thicknesses of the two light-emitting elements.

In another optional implementation, H1>H2 and H3<H4, that is, the thickness of the P electrode is greater than the thickness of the N electrode in the first light-emitting element 101 but the thickness of the P electrode is less than the thickness of the N electrode in the second light-emitting element 102. As described above, when the emitted color of the first light-emitting element 101 is different from the emitted color of the second light-emitting element 102 or the first light-emitting element 101 and the second light-emitting element 102 are located in different display regions, the requirements for the two different light-emitting elements may be completely different. For example, the first light-emitting element 101 is required to have a high brightness and a fast luminescence response speed, and the second light-emitting element 102 is required to be controlled in the size of the light-emitting area or the size of the electrode. In this case, the designs of the first light-emitting element 101 and the second light-emitting element 102 need to be greatly different, and thus the case in which H1>H2 and H3<H4 may occur.

For example, |H1−H2|<|H3−H4|, that is, the thickness difference between the P electrode and the N electrode in the first light-emitting element 101 is less than the thickness difference between the P electrode and the N electrode in the second light-emitting element 102. When H1>H2 and H3<H4, the thickness of the P electrode is set to be less than the thickness of the N electrode in the second light-emitting element 102. Although the thickness of the P electrode may be set to be less than the thickness of the N electrode due to special functional requirements, as described above, to ensure the ability of the P electrode to provide a positive signal, the thickness of the P electrode is generally not set too small, and thus, it is set that |H1−H2|<|H3−H4| here.

Optionally, in this embodiment, |H1−H3|≠|H2−H4|, that is, the thickness difference between the P electrode in the first light-emitting element 101 and the P electrode in the second light-emitting element 102 is different from the thickness difference between the N electrode in the first light-emitting element 101 and the N electrode in the second light-emitting element 102.

As described above, the emitted color of the first light-emitting element 101 is different from the emitted color of the second light-emitting element 102 or the first light-emitting element 101 and the second light-emitting element 102 are located in different display regions, and thus, the light emission requirements for the two light-emitting elements may be different. To match the different light emission requirements, it is set that |H1−H3|≠|H2−H4|, thereby independently adjusting the electrode thicknesses of the two light-emitting elements.

Optionally, in this embodiment, H1>H3 and/or H2>H4; or H1<H3 and/or H2<H4, that is, the thickness of the P electrode in the first light-emitting element 101 is greater than the thickness of the P electrode in the second light-emitting element 102 and/or the thickness of the N electrode in the first light-emitting element 101 is greater than the thickness of the N electrode in the second light-emitting element 102; or the thickness of the P electrode in the first light-emitting element 101 is less than the thickness of the P electrode in the second light-emitting element 102 and/or the thickness of the N electrode in the first light-emitting element 101 is less than the thickness of the N electrode in the second light-emitting element 102. When the size of the first light-emitting element 101 is larger than the size of the second light-emitting element 102, the emission efficiency of the first light-emitting element 101 is lower than the emission efficiency of the second light-emitting element 102 or the luminescence response voltage of the first light-emitting element 101 is higher than the luminescence response voltage of the second light-emitting element 102, the thicknesses of the electrodes in the first light-emitting element 101 are larger, and thus, H1>H3 and/or H2>H4. Otherwise, when the size of the first light-emitting element 101 is smaller than the size of the second light-emitting element 102, the emission efficiency of the first light-emitting element 101 is higher than the emission efficiency of the second light-emitting element 102 or the luminescence response voltage of the first light-emitting element 101 is lower than the luminescence response voltage of the second light-emitting element 102, the thicknesses of the electrodes in the first light-emitting element 101 are smaller, and thus, H1<H3 and/or H2<H4.

Optionally, in this embodiment, |H1−H3|>|H2−H4| or |H1−H3|<|H2−H4|, that is, the thickness difference between the P electrode in the first light-emitting element 101 and the P electrode in the second light-emitting element 102 is not equal to the thickness difference between the N electrode in the first light-emitting element 101 and the N electrode in the second light-emitting element 102. Since the thickness of the P electrode and the thickness of the N electrode in the light-emitting element can often be independently adjusted, the thickness difference of the P electrodes and the thickness difference of the N electrodes can be independently adjusted in this embodiment to match the light emission requirements for different light-emitting elements. In this manner, in some cases, the case in which |H1−H3|>|H2−H4| may occur, and in other cases, the case in which |H1−H3|<|H2−H4| may occur.

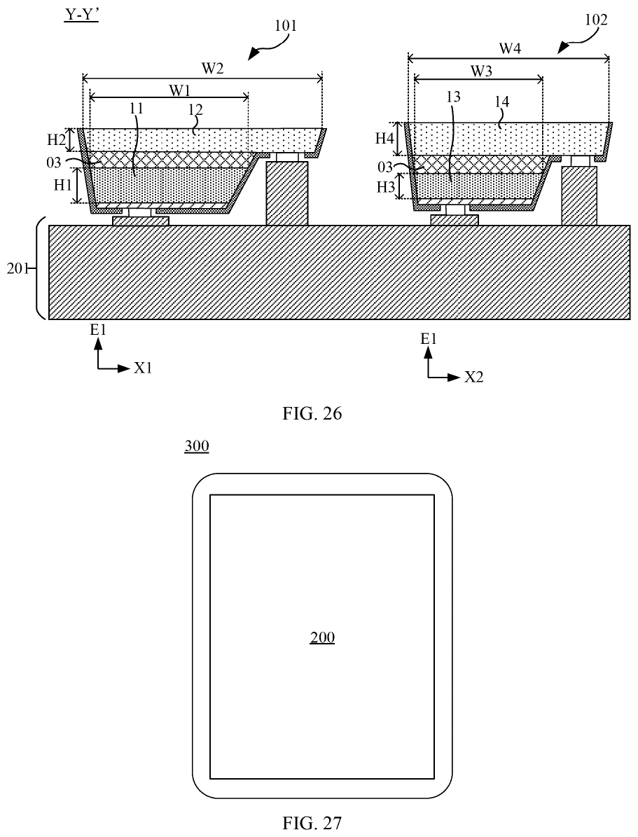

Optionally, in this embodiment, H1>H3 and H2<H4; or H1<H3 and H2>H4, that is, the thickness of the P electrode in the first light-emitting element 101 is greater than the thickness of the P electrode in the second light-emitting element 102 but the thickness of the N electrode in the first light-emitting element 101 is less than the thickness of the N electrode in the second light-emitting element 102; or the thickness of the P electrode in the first light-emitting element 101 is less than the thickness of the P electrode in the second light-emitting element 102 but the thickness of the N electrode in the first light-emitting element 101 is greater than the thickness of the N electrode in the second light-emitting element 102. For example, FIG. 26 is another section view of the display panel taken along YY′ in FIG. 18. FIG. 26 is illustrated by using an example in which H1>H3 and H2>H4. When the sizes of the electrodes in the first light-emitting element 101 and the second light-emitting element 102 need to be independently adjusted, the case described above may occur, that is, the case in which the thickness of the N electrode in the light-emitting element with the P electrode having a large thickness is small or the case in which the thickness of the N electrode in the light-emitting element with the P electrode having a small thickness is large may occur.

Optionally, in this embodiment, in a first preset direction X1, the width of the first electrode 11 is W1, and the width of the second electrode 12 is W2, where the first preset direction X1 is parallel to the surface of the first light-emitting element 101; in a second preset direction X2, the width of the third electrode 13 is W3, and the width of the fourth electrode 14 is W4, where the second preset direction X2 is parallel to the surface of the second light-emitting element 102; where W1≠W2 and/or W3≠W4. It is to be noted that FIGS. 24 to 26 are illustrated by using an example in which the first preset direction X1 and the second preset direction X2 are the same direction. In other embodiments, the first preset direction X1 and the second preset direction X2 may also be directions that are parallel to the same surface (for example, the surface of the first light-emitting element 101 or the surface of the second light-emitting element 102) but intersect each other.

As described above, the emitted color of the first light-emitting element 101 is different from the emitted color of the second light-emitting element 102 or the first light-emitting element 101 and the second light-emitting element 102 are located in different display regions, and thus, the light emission requirements for the two light-emitting elements may be different. To match the different light emission requirements, W1≠W2 and/or W3≠W4, thereby independently setting the widths of the P electrode and the N electrode in the first light-emitting element 101 and/or independently setting the widths of the P electrode and the N electrode in the second light-emitting element 102.

Optionally, in this embodiment, |W1−W2|≠|W3−W4|, that is, the width difference between the P electrode and the N electrode in the first light-emitting element 101 is not equal to the width difference between the P electrode and the N electrode in the second light-emitting element 102, thereby independently setting the sizes of the respective electrodes in the first light-emitting element 101 and the second light-emitting element 102.

Optionally, in this embodiment, the voltage value of the signal received by the first electrode 11 is greater than the voltage value of the signal received by the second electrode 12, that is, the first electrode 11 is a P electrode and the second electrode 12 is an N electrode. The voltage value of the signal received by the third electrode 13 is greater than the voltage value of the signal received by the fourth electrode 14, that is, the third electrode 13 is a P electrode and the fourth electrode 14 is an N electrode.

Optionally, in some optional implementations, W1<W2 and/or W3<W4; or W1>W2 and/or W3>W4, that is, the width of the P electrode is less than the width of the N electrode in the first light-emitting element 101 and/or the width of the P electrode is less than the width of the N electrode in the second light-emitting element 102; or the width of the P electrode is greater than the width of the N electrode in the first light-emitting element 101 and/or the width of the P electrode is greater than the width of the N electrode in the second light-emitting element 102. In such a case, the trends of the size difference between the P electrode and the N electrode in the first light-emitting element 101 and the second light-emitting element 102 are consistent with each other. For example, when the N electrode is located on one side, facing the light emission surface, of the P electrode, the width of the N electrode is generally set to be greater than the width of the P electrode, and when the P electrode is located on one side, facing the light emission surface, of the N electrode, the width of the P electrode is generally set to be greater than the width of the N electrode. When the trends of the size difference between the P electrode and the N electrode in the first light-emitting element 101 and the second light-emitting element 102 are consistent with each other, the preparation processes of the two light-emitting elements are similar to each other, thereby simplifying the process.

In other optional implementations, W1>W2 and W3<W4; or W1<W2 and W3>W4, that is, the width of the P electrode is greater than the width of the N electrode in the first light-emitting element 101 but the width of the P electrode is less than the width of the N electrode in the second light-emitting element 102; or the width of the P electrode is less than the width of the N electrode in the first light-emitting element 101 but the width of the P electrode is greater than the width of the N electrode in the second light-emitting element 102. The trends of the size difference between the P electrode and the N electrode in the first light-emitting element 101 and the second light-emitting element 102 are opposite to each other. When the emitted color of the first light-emitting element 101 is different from the emitted color of the second light-emitting element 102 or the first light-emitting element 101 and the second light-emitting element 102 are located in different display regions, the case described above may occur to independently adjust the widths of different light-emitting elements, thereby meeting the light emission requirements of different light-emitting elements.

Optionally, in this embodiment, W1>W3 and/or W2>W4; or W1<W3 and/or W2<W4, that is, the width of the P electrode in the first light-emitting element 101 is greater than the width of the P electrode in the second light-emitting element 102 and/or the width of the N electrode in the first light-emitting element 101 is greater than the width of the N electrode in the second light-emitting element 102; or the width of the P electrode in the first light-emitting element 101 is less than the width of the P electrode in the second light-emitting element 102 and/or the width of the N electrode in the first light-emitting element 101 is less than the width of the N electrode in the second light-emitting element 102. When the size of one of the first light-emitting element 101 or the second light-emitting element 102 is required to be larger than the size of the other, the case described above may occur.

Optionally, in this embodiment, W1>W3 and W2<W4; or W1<W3 and W2>W4, that is, the width of the P electrode in the first light-emitting element 101 is greater than the width of the P electrode in the second light-emitting element 102 but the width of the N electrode in the first light-emitting element 101 is less than the width of the N electrode in the second light-emitting element 102; or the width of the P electrode in the first light-emitting element 101 is less than the width of the P electrode in the second light-emitting element 102 but the width of the N electrode in the first light-emitting element 101 is greater than the width of the N electrode in the second light-emitting element 102. In some cases, the case in which the width of the P electrode of the light-emitting element is large but the width of the N electrode is small or the case in which the width of the P electrode of the light-emitting element is small but the width of the N electrode is large may occur, depending on the specific design requirements.

Optionally, in this embodiment, |W1−W3|>|W2−W4| or |W1−W3|<|W2−W4|, that is, the width difference between the P electrode in the first light-emitting element 101 and the P electrode in the second light-emitting element 102 is not equal to the width difference between the N electrode in the first light-emitting element 101 and the N electrode in the second light-emitting element 102. Since the P electrode and the N electrode are different from each other in both the material and the signal to be transmitted, the P electrodes and the N electrodes are independently adjusted for the first light-emitting element 101 and the second light-emitting element 102, thereby matching the respective light emission requirements of different light-emitting elements.

Based on the same concept, the embodiments of the present disclosure further provide a display device. FIG. 27 is a structure diagram of a display device according to an embodiment of the present disclosure. As shown in FIG. 27, the display device 300 includes the display panel 200 provided by any of the embodiments of the present disclosure and thus, the display device 300 has the same beneficial effects as the display panel 200 and the light-emitting element 100 described above. For similarities, reference may be made to the descriptions in the preceding embodiments. The details are not repeated here. For example, the display device may be a micro-LED display panel. In addition, the display device 300 provided by this embodiment of the present disclosure may be a cellphone shown in FIG. 27 or may be any electronic product having a display function. The electronic product includes, but is not limited to, a television set, a laptop, a desktop display, a tablet, a digital camera, a smart bracelet, smart glasses, an in-vehicle display, a medical device, an industrial control device or a touch interactive terminal, which is not limited in the embodiments of the present disclosure.

The preceding embodiments are not construed as a limitation of the scope of the present disclosure. It is to be understood by those skilled in the art that various modifications, combinations, sub-combinations, and substitutions may be performed according to design requirements and other factors. Any modifications, equivalent substitutions, improvements and the like made within the spirit and principle of the present disclosure are within the scope of the present disclosure.

What is claimed is:

1. A light-emitting element, comprising:
a first electrode;
a reflective layer, wherein at least a part of a region of the reflective layer is located on one side, facing away from a light emission surface, of the first electrode; and
a first connection electrode, wherein the first electrode receives a signal through the first connection electrode;
wherein the first electrode is connected to the first connection electrode, the reflective layer comprises a first reflective region, and the first reflective region and the first connection electrode are located on a same side of the first electrode.

2. The light-emitting element according to claim 1, wherein the reflective layer comprises N Bragg reflective layers, wherein N≥1;
at least one of the N Bragg reflective layers each comprises a first reflective sub-layer and a second reflective sub-layer, wherein at least one of following applies: a refractive index of the first reflective sub-layer is different from a refractive index of the second reflective sub-layer or a thickness of the first reflective sub-layer is different from a thickness of the second reflective sub-layer.

3. The light-emitting element according to claim 1, wherein
the first reflective region is located between a layer in which the first electrode is located and a layer in which the first connection electrode is located.

4. The light-emitting element according to claim 3, wherein
the first electrode comprises a first region and a second region, wherein the first region is connected to the first connection electrode, and a spacing between a layer in which the second region is located and the layer in which the first connection electrode is located in a first direction is D1, wherein the first direction is a direction perpendicular to a surface of the light-emitting element;
wherein D1>0.

5. The light-emitting element according to claim 4, wherein
a thickness of the first reflective region in the first direction is Hr1;
wherein D1≥Hr1.

6. The light-emitting element according to claim 4, wherein
the first reflective region comprises a first surface and a second surface, wherein the first surface is in contact with the second region of the first electrode, and the second surface is in contact with the first connection electrode.

7. The light-emitting element according to claim 4, wherein
the light-emitting element further comprises a current spreading layer, and the first reflective region comprises a first surface and a second surface;
wherein the current spreading layer is located between the first surface and the second region of the first electrode, and the second surface is in contact with the first connection electrode.

8. The light-emitting element according to claim 7, wherein
a thickness of the current spreading layer in the first direction is Hs;
wherein Hs<Hr1.

9. The light-emitting element according to claim 7, wherein
at least one side surface of the first reflective region is in contact with the first region of the first electrode; or
at least one side surface of the first reflective region is in contact with the current spreading layer.

10. The light-emitting element according to claim 4, wherein
a thickness of the first region in the first direction is He1, and a thickness of the second region in the first direction is He2;
wherein He1>He2.

11. The light-emitting element according to claim 10, wherein
the first region comprises a first protrusion, wherein the first protrusion is located on one side, facing the first connection electrode, of the first region, and a thickness of the first protrusion in the first direction is Hp1;
wherein He1−Hp1≤He2.

12. The light-emitting element according to claim 11, wherein the first protrusion comprises a first top portion and a first bottom portion, wherein the first top portion is connected to the first connection electrode, a width of the first top portion in a second direction is Wp1, and a width of the first bottom portion in the second direction is Wp2, wherein the second direction is perpendicular to the first direction;
wherein Wp1≠Wp2.

13. The light-emitting element according to claim 12, wherein Wp1<Wp2.

14. The light-emitting element according to claim 12, wherein Wp1>Wp2.

15. The light-emitting element according to claim 4, wherein at least one of following applies:
the first region and the second region of the first electrode are formed integrally; or
the first region and the second region of the first electrode contain a same material.

16. The light-emitting element according to claim 1 wherein
the first reflective region does not overlap the first connection electrode in a first direction, wherein the first direction is a direction perpendicular to a surface of the light-emitting element.

17. The light-emitting element according to claim 16, wherein
a first spacing P1 exists between the first reflective region and the first connection electrode in a second direction, wherein P1>0, and the second direction is perpendicular to the first direction.

18. The light-emitting element according to claim 1, wherein
the first reflective region partially overlaps the first connection electrode in a first direction,
wherein the first direction is a direction perpendicular to a surface of the light-emitting element.

19. The light-emitting element according to claim 18, wherein
the first connection electrode comprises a first top surface and a second top surface, wherein the first top surface is located on one side, facing the first electrode, of the second top surface, a width of the first top surface in a second direction is Hc11, and a width of the second top surface in the second direction is Hc12, wherein the second direction is perpendicular to the first direction;
wherein Hc11<Hc12.

20. A display device, comprising a display panel, wherein the display panel comprises a light-emitting element which comprises:
a first electrode;
a reflective layer, wherein at least a part of a region of the reflective layer is located on one side, facing away from a light emission surface, of the first electrode; and
a first connection electrode, wherein the first electrode receives a signal through the first connection electrode;
wherein the first electrode is connected to the first connection electrode, the reflective layer comprises a first reflective region, and the first reflective region and the first connection electrode are located on a same side of the first electrode.
